(19) United States
(12) Patent Application Publication
(10) Pub. No.: US 2026/0047254 A1
(43) Pub. Date: Feb. 12, 2026

(54) DISPLAY DEVICE AND METHOD FOR FABRICATING THE SAME

(71) Applicant: LG Display Co., Ltd., Seoul (KR)

(72) Inventors: Bong Seok CHOI, Paju-si (KR); Se Jun YOON, Paju-si (KR)

(73) Assignee: LG Display Co., Ltd., Seoul (KR)

(21) Appl. No.: 19/234,984

(22) Filed: Jun. 11, 2025

(30) Foreign Application Priority Data
Aug. 7, 2024 (KR) 10-2024-0105528

(51) Int. Cl. H10H 29/41; H10H 29/01; H10H 29/49

(52) U.S. Cl. CPC H10H 29/41; H10H 29/012; H10H 29/49

(57) ABSTRACT

A display device and a method for manufacturing the same are disclosed. The display device includes an adhesive layer on a substrate, the adhesive layer comprising a driving circuit chip transfer portion having a plurality of support patterns spaced apart from one another and a pass hole positioned therebetween. A driving circuit chip is disposed on the support patterns. A planarization layer is formed over the driving circuit chip and the adhesive layer, followed by an insulating layer on the planarization layer. A plurality of light emitting elements is then positioned on the insulating layer and electrically connected to the driving circuit chip. The method for manufacturing the display device includes sequentially forming and arranging the adhesive layer, the driving circuit chip, the planarization and insulating layers, and the light emitting elements. This structure facilitates efficient chip transfer and alignment while supporting improved device performance and production reliability.

### CROSS-REFERENCE TO RELATED APPLICATION

This application claims priority to and the benefit of Korean Patent Application No. 10-2024-0105528, filed Aug. 7, 2024, the specification of which is incorporated herein by reference in its entirety.

### BACKGROUND

### Technical Field

The present disclosure relates to a display device and a method for fabricating the same.

### Description of the Related Art

A display device may include an organic light emitting display device (OLED) that emits light by itself, or a liquid crystal display device (LCD) that requires a separate light source.

Recently, a display device including a light emitting diode (LED) has gained attention as a next-generation display device. Since the light emitting diode (LED) is formed of an inorganic material rather than an organic material, it provides a faster lighting response time, superior light emitting efficiency, and the capability to display high-luminance images compared to the liquid crystal display device or the organic light emitting display device.

### BRIEF SUMMARY

The disclosed display device and fabrication method utilize an adhesive layer that includes spaced-apart support patterns with intervening pass holes. These pass holes allow foreign particles and residual solvents to be discharged, improving the yield of micro driving circuit chip transfers. The micro driving circuit chips are integrated directly into the display area, replacing individual sub-pixel components and contributing to a more compact structure, greater energy efficiency, and simplified manufacturing.

To further improve production reliability, each sub-pixel includes both a primary and a redundant micro light emitting diode, ensuring continued function even in the presence of transfer defects. The structure also includes multiple planarization and insulating layers to support complex wiring and enable flexible or foldable display configurations. Signal lines are designed with stress-relieving patterns to resist cracking in bent regions, and a reflective electrode layer serves both as a light reflector and a positioning aid during assembly, enhancing precision and overall device performance.

Various embodiments disclosed herein describe a method of transferring a micro driving circuit chip onto a panel substrate, which may be applied during the fabrication of a display device that incorporates micro light emitting elements.

Various embodiments of the present disclosure provide a display device and a method for fabricating the same, capable of improving transfer yield by reducing the risk of foreign particles being present at a transfer position of a micro driving circuit chip.

The technical problems in the related art are not limited to those described above, and other problems not mentioned herein will be clearly understood by those skilled in the art from the following description.

A display device according to various embodiments of the present disclosure may include: an adhesive layer positioned on a substrate and including a driving circuit chip transfer portion having a plurality of support patterns spaced apart from each other and a pass hole; a driving circuit chip positioned on the plurality of support patterns; a planarization layer positioned on the driving circuit chip and the adhesive layer; an insulating layer positioned on the planarization layer; and a plurality of light emitting elements positioned on the insulating layer and connected to the driving circuit chip.

A method for fabricating a display device according to various embodiments of the present disclosure may include: positioning an adhesive layer on a substrate, the adhesive layer including a driving circuit chip transfer portion having a plurality of support patterns spaced apart from each other and a pass hole positioned between the plurality of support patterns; positioning a driving circuit chip on the plurality of support patterns; positioning a planarization layer on the adhesive layer and the driving circuit chip; positioning an insulating layer on the planarization layer; and positioning a plurality of light emitting elements connected to the driving circuit chip on the insulating layer.

Other specific aspects according to various examples of the present disclosure, apart from the above-mentioned means for solving the problems, are included in the following description and drawings.

According to the present disclosure, a plurality of support patterns spaced apart from each other may be formed in a driving circuit chip transfer portion of an adhesive layer and a pass hole may also be formed between the support patterns, to allow foreign particles or residual solvents to be discharged to the outside through the pass hole. Accordingly, the risk of foreign particles being present at the transfer position of the micro driving circuit chip may be reduced, thereby improving the transfer yield.

The effects of the present disclosure are not limited to those described above, and other effects not explicitly mentioned will be clearly understood by those skilled in the art from the following description.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is an exploded perspective view of a display device according to an embodiment of the present disclosure;

FIG. 2 is a plan view of a display device according to an embodiment of the present disclosure;

FIG. 3 is an enlarged plan view illustrating a connection structure of a display device according to an embodiment of the present disclosure;

FIG. 4 is a diagram illustrating a circuit structure according to an embodiment of the present disclosure;

FIG. 5 is a plan view of a display device according to an embodiment of the present disclosure;

FIG. 6 is a plan view of a display device according to an embodiment of the present disclosure;

FIG. 7 is a plan view of a display device according to an embodiment of the present disclosure;

FIG. 8 is a cross-sectional view taken along line I-I′ in FIG. 3;

FIG. 9 is an enlarged cross-sectional view of a display device according to an embodiment of the present disclosure;

FIG. 10 is an enlarged cross-sectional view of a display device according to an embodiment of the present disclosure;

FIG. 11 is an enlarged plan view of a display device according to an embodiment of the present disclosure;

FIG. 12 is a cross-sectional view taken along line II-II′ in FIG. 11, illustrating a display device according to one embodiment of the present disclosure;

FIG. 13 is a cross-sectional view taken along line II-II′ of FIG. 11, illustrating a display device according to another embodiment of the present disclosure;

FIG. 14 is an enlarged plan view of a display device according to still another embodiment of the present disclosure;

FIGS. 15A to 15D are cross-sectional views illustrating fabricating processes of a display device according to one embodiment of the present disclosure; and

FIGS. 16 to 19 are views illustrating devices to which a display device according to embodiments of the present disclosure is applied.

### DETAILED DESCRIPTION

The advantages and features of the present disclosure, and methods of achieving them will become apparent upon reference to the embodiments described in detail below in conjunction with the accompanying drawings. However, the present disclosure is not limited to the following embodiments disclosed herein, but may be implemented in various different forms; rather, the present embodiments are provided to make the disclosure of the present disclosure complete and to enable those skilled in the art to fully comprehend the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Identical reference numerals may designate identical components throughout the description. Further, in describing the present disclosure, detailed descriptions of related known technologies may be omitted so as not to obscure the essence of the present disclosure. Terms such as, “including,” “having,” or “comprising” as used herein are generally intended to allow for the addition of other components, unless the terms are used with the term “only.” References to components of a singular noun include the plural of that noun, unless specifically stated otherwise.

In the interpretation of components, they are construed to include margins of error, even if not explicitly stated.

When describing a positional relationship, for example, “on top of,” “above,” “below,” “next to,” or “adjacent to” describes the positional relationship of two parts, one or more other parts may be located between the two parts, unless “immediately,” “directly,” or “near to” is used.

When describing a temporal relationship, “after,” “following,” “next to,” or “before” describes a temporal antecedent or consequent relationship, which may not be continuous unless “immediately” or “directly” is used.

The first, the second, and so on are used to describe various components, but these components are not limited by these terms. These terms are used only to distinguish one component from another. Therefore, the first component referred to below may be a second component within the technical spirit of the present disclosure.

Terms such as first, second, A, B, (a), or (b) may be used to describe elements of the present disclosure. Such terms are intended only to distinguish one component from another and are not intended to define the nature, sequence, order, or number of such components.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

When a component is described as being “connected,” “coupled,” “accessed,” or “attached” to another component, it is to be understood that the component may be directly connected, coupled, accessed, or attached to the other component, but that there may also be other components interposed between the respective components which may be indirectly connected, coupled, accessed, or attached, unless specifically stated otherwise.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When a component is described as being “in contacted” or “overlapped” with another component, it is to be understood that the component may be in direct contacted or overlap with the other component, but that there may also be other components “interposed” between the respective components which may be in direct or indirect contacted or overlap with, unless specifically stated otherwise.

It should be understood that the term “at least one” includes all possible combinations of one or more related components. For example, the meaning of “at least one of the first, second, and third components” may be understood to include not only the first, second, or third component, but also any combination of two or more of the first, second, and third components.

The terms the first direction, the second direction, the third direction, the X-axis direction, the Y-axis direction, and the Z-axis direction are not to be interpreted solely as a geometric relationship in which the relationship to one another is perpendicular, but may refer to a broader range of orientations in which the configurations of the present disclosure may function.

Each of the features of various embodiments of the present disclosure may be coupled or combined with one another in whole or in part, and may be technologically interlocked and operated in various ways, and each of the embodiments may be carried out independently or in conjunction with one another.

Hereinafter, various embodiments of the present disclosure will be described in detail with reference to the accompanying drawings.

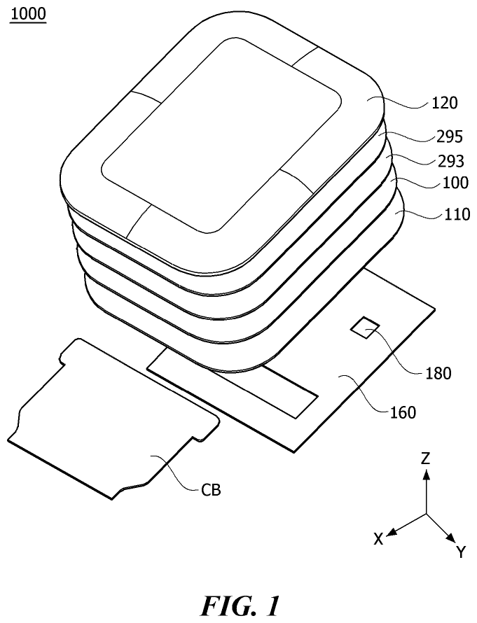

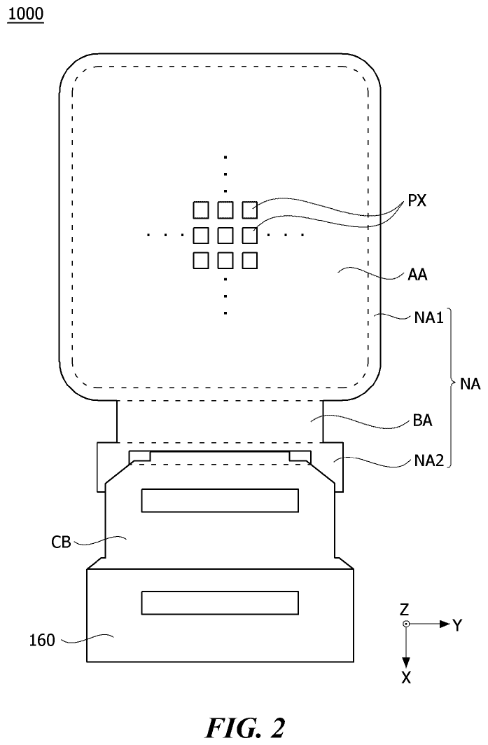

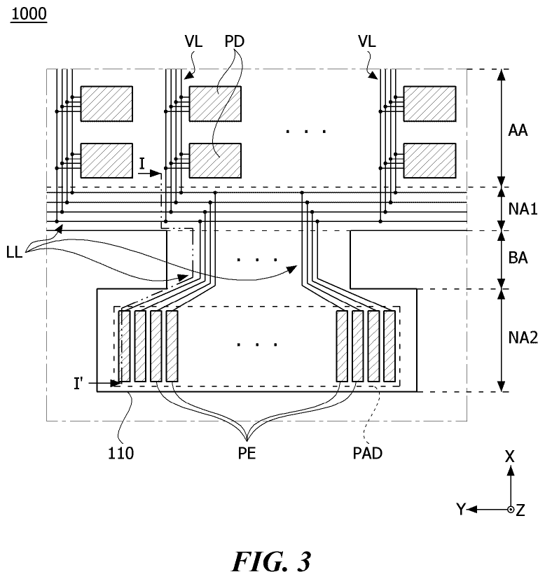

FIG. 1 is an exploded perspective view of a display device according to an embodiment of the present disclosure. FIG. 2 is a plan view of a display device according to an embodiment of the present disclosure. FIG. 3 is an enlarged plan view illustrating a connection structure of a display device according to an embodiment of the present disclosure.

Referring to FIGS. 1 and 2, a display device 1000 according to an embodiment of the present disclosure may include a display panel 100, a polarizing layer 293, an adhesive layer 295, a cover member 120, a substrate 110, a flexible circuit board CB, and a printed circuit board 160.

For example, the display device 1000 may include the substrate 110. The substrate 110 may be a member that supports other components of the display device 1000. The substrate 110 may be formed of an insulating material. For example, the substrate 110 may be formed of glass or resin. In addition, the substrate 110 may be formed of a material having flexibility. For example, the substrate 110 may be formed of a plastic material having flexibility, such as polyimide (PI). However, the embodiments of the present disclosure are not limited thereto.

The display panel 100 may implement information, video, and/or an image provided to a user. For example, the display panel 100 may include a display area AA and a non-display area NA. For example, the substrate 110 may include the display area AA and the non-display area NA. The display area AA and the non-display area NA are not limited to being described only with respect to the substrate 110 but may be described throughout the entire display device 1000.

The display area AA may be an area in which an image is displayed. The display area AA may include a plurality of pixels PX. Each of the plurality of pixels PX may be composed of a plurality of sub-pixels. A plurality of light emitting elements may be respectively arranged in the plurality of sub-pixels. The plurality of light emitting elements may be configured differently depending on the type of display device 1000. For example, when the display device 1000 is an inorganic light emitting display device, the light emitting element may be a light emitting diode (LED), a micro light emitting diode (micro LED), or a mini light emitting diode (mini LED), but the embodiments of the present disclosure are not limited thereto.

The non-display area NA may be an area in which no image is displayed. Various wires and circuits for driving the plurality of pixels PX of the display area AA may be positioned in the non-display area NA. For example, in the non-display area NA, various wires and driving circuits may be mounted, and a pad portion PAD to which an integrated circuit, a printed circuit, and the like are connected may be provided, but the embodiments of the present disclosure are not limited thereto.

For example, the driving circuits may be a data driving circuit and/or a gate driving circuit, but the embodiments of the present disclosure are not limited thereto. Wires through which a control signal for controlling the driving circuits is supplied may be provided. For example, the control signal may include various timing signals including a clock signal, an input data enable signal, and synchronization signals, but the embodiments of the present disclosure are not limited thereto. The control signal may be received through the pad portion PAD. For example, link wires LL for transmitting signals may be positioned in the non-display area NA. For example, the pad portion PAD may be connected to driving components such as the flexible circuit board CB and the printed circuit board 160.

According to the present disclosure, the non-display area NA may include a first non-display area NA1, a bending area BA, and a second non-display area NA2. For example, the first non-display area NA1 may be an area that surrounds at least a portion of the display area AA. The bending area BA may be an area extending from at least one of the plurality of sides of the first non-display area NA1, and may be a bendable area. The second non-display area NA2 may be an area extending from the bending area BA, and the pad portion PAD may be positioned in the second non-display area NA2. For example, the bending area BA may be in a bent state, and the remaining area of the substrate 110, excluding the bending area BA, may be in a flat state. In this case, as the bending area BA is in a bent state, the second non-display area NA2 may be positioned on the rear surface of the display area AA. However, the embodiments of the present disclosure are not limited thereto.

The display area AA of the substrate 110 or the display device 1000 may be configured in various shapes depending on the design of the display device 1000. For example, the display area AA may be configured in a rectangular shape with four rounded corners, but the embodiments of the present disclosure are not limited thereto. In another example, the display area AA may be configured in a rectangular shape with four right-angled corners, a circular shape, or the like, but the embodiments of the present disclosure are not limited thereto.

According to the present disclosure, the width of the second non-display area NA2 in which a plurality of pad electrodes PE are arranged may be greater than the width of the bending area BA in which only the plurality of link wires LL are arranged. Additionally, the width of the display area AA in which the plurality of sub-pixels are arranged may be greater than the width of the bending area BA in which only the plurality of link wires LL are arranged. In the drawings, the bending area BA is illustrated as having a width smaller than that of other areas of the substrate 110. However, the shape of the substrate 110 including the bending area BA is merely exemplary, and the embodiments of the present disclosure are not limited thereto.

Referring to FIG. 2, in the display device according to an embodiment of the present disclosure, the display area AA in which the plurality of pixels PX are arranged and the first non-display area NA1 surrounding the display area AA may be positioned.

Referring to FIG. 3, a plurality of driving circuit chips PD may be arranged in the display area AA. The plurality of driving circuit chips PD may be circuits for driving the light emitting elements of the plurality of sub-pixels. Each of the plurality of driving circuit chips PD may include a plurality of transistors including a driving transistor, a storage capacitor, and the like and may supply a control signal, power, and a driving current to the light emitting elements of the plurality of sub-pixel to control the light emission operation of the plurality of light emitting elements. For example, the driving circuit chip PD may include a power wire and a signal wire for controlling the on/off state and/or light emission time of the light emitting element. For example, the plurality of driving circuit chips PD may be a driving driver manufactured using a metal-oxide-silicon field effect transistor (MOSFET) fabrication process on a semiconductor substrate, but the embodiments of the present disclosure are not limited thereto. The driving driver may include the plurality of driving circuit chips PD and may drive the plurality of sub-pixels.

Referring also to FIG. 1, the flexible circuit board CB and the printed circuit board 160 may be positioned below the display panel 100. The flexible circuit board CB and the printed circuit board 160 may be positioned on at least one edge of the display panel 100, but the embodiments of the present disclosure are not limited thereto. One side of the flexible circuit board CB may be attached to the display panel 100, and the other side thereof may be attached to the printed circuit board 160, but the embodiments of the present disclosure are not limited thereto. The flexible circuit board CB may be a flexible film, but the embodiments of the present disclosure are not limited thereto.

The pad portion PAD including the plurality of pad electrodes PE may be positioned in the second non-display area NA2. Driving components, including one or more flexible circuit boards (or flexible films) CB and the printed circuit board 160, may be attached or bonded to the pad portion PAD. The plurality of pad electrodes PE of the pad portion PAD may be electrically connected to the one or more flexible circuit boards (or flexible films) CB, and may transmit various signals (or power) from the printed circuit board 160 and the flexible circuit board (or flexible film) CB to the plurality of driving circuit chips PD of display area AA.

The flexible circuit board (or flexible film) CB may be a film in which various components are arranged on a base film having flexibility. For example, a driving IC, such as a gate driver IC or a data driver IC, may be positioned on the flexible circuit board (or flexible film) CB, but the embodiments of the present disclosure are not limited thereto. The driving IC may be a component that processes a driving signal and data for displaying an image. The driving IC may be provided using a method such as a chip-on-glass (COG), a chip-on-film (COF), or a tape carrier package (TCP) depending on the mounting method, but the embodiments of the present disclosure are not limited thereto. The flexible circuit board (or flexible film) CB may be attached to or bonded onto the plurality of pad electrodes PE through a conductive adhesive layer, but the embodiments of the present disclosure are not limited thereto.

The printed circuit board 160 may be electrically connected to the one or more flexible circuit boards (or flexible films) CB and may be a component for supplying a signal to the driving IC. The printed circuit board 160 may be positioned on one side of the flexible circuit board (or flexible film) CB and electrically connected to the flexible circuit board (or flexible film) CB. Various components for supplying various signals to the driving IC may be mounted on the printed circuit board 160. For example, various components such as a timing controller, a power supply, a memory, or a processor may be positioned in the printed circuit board 160. For example, the printed circuit board 160 may include a power management integrated circuit (PMIC), but the embodiments of the present disclosure are not limited thereto.

The printed circuit board 160 may include at least one hole 180, but the embodiments of the present disclosure are not limited thereto. An internal component for sensing ambient light, temperature, or the like, which can be provided to a plurality of sensors, may be positioned in a region corresponding to the at least one hole 510. For example, the internal component may include an ambient light sensor (ALS), a temperature sensor, or the like, but the embodiments of the present disclosure are not limited thereto. For example, the hole 180 may be a transmission hole or the like, but the embodiments of the present disclosure are not limited thereto.

Referring to FIG. 1, the polarizing layer 293 may be positioned on the display panel 100. The polarizing layer 293 may prevent or reduce light generated from an external light source from entering the interior of the display panel 100 and affecting the light emitting elements or the like.

The cover member 120 may be positioned on the polarizing layer 293. The cover member 120 may be a member for protecting the display panel 100. The adhesive layer 295 may be positioned between the polarizing layer 293 and the cover member 120. The cover member 120 may be attached to the display panel 100 by using the adhesive layer 295. The adhesive layer 295 may include an optically clear adhesive (OCA), an optically clear resin (OCR), a pressure sensitive adhesive (PSA), or the like, but the embodiments of the present disclosure are not limited thereto.

The substrate 110 may be positioned between the display panel 100 and the printed circuit board 160. The substrate 110 may reinforce the rigidity of the display panel 100. The substrate 110 may be a back plate, but the embodiments of the present disclosure are not limited thereto.

Referring to FIGS. 1 to 3, the plurality of link wires LL may be arranged in the first and second non-display areas NA1 and NA2. The plurality of link wires LL may be wires for transmitting various signals from the one or more flexible circuit boards (or flexible films) 400 and the printed circuit board 160 to the display area AA. The plurality of link wires LL may extend from the plurality of pad electrodes PE of the second non-display area NA2 toward the bending area BA and the first non-display area NA1, and may be electrically connected to a plurality of driving wires VL of the display area AA. The plurality of driving circuit chips PD may be driven by receiving signals from the one or more flexible circuit boards (or flexible films) CB and the printed circuit board 160 through the driving wires VL of the display area AA and the link wires LL of the non-display area NA.

For example, the plurality of driving wires VL, together with the plurality of link wires LL, may serve as wires for transmitting signals outputted from the flexible circuit board (or flexible film) CB and the printed circuit board 160 to the plurality of driving circuit chips PD. The plurality of driving wires VL may be arranged in the display area AA and electrically connected to the plurality of driving circuit chips PD. The plurality of driving wires VL may extend from the display area AA toward the non-display area NA and be electrically connected to the plurality of link wires LL. Accordingly, signals outputted from the flexible circuit board (or flexible film) CB and the printed circuit board 160 may be transmitted to the driving circuit chips PD through the plurality of link wires LL and the plurality of driving wires VL.

As the bending area BA is bent, portions of the plurality of link wires LL may also be bent together. Stress may be concentrated on the bent portions of the link wires LL, thereby causing cracks in the link wires LL. Accordingly, the plurality of link wires LL may be formed of a conductive material having excellent flexibility to reduce cracks when the bending area BA is bent. For example, the plurality of link wires LL may be formed of a conductive material having excellent flexibility, such as gold (Au), silver (Ag), or aluminum (Al), but the embodiments of the present disclosure are not limited thereto.

Additionally, the plurality of link wires LL may be formed of one of various conductive materials used in the display area AA. For example, the plurality of link wires LL may be formed of molybdenum (Mo), chromium (Cr), titanium (Ti), nickel (Ni), neodymium (Nd), copper (Cu), an alloy of silver (Ag) and magnesium (Mg), or another alloy thereof, but the embodiments of the present disclosure are not limited thereto. The plurality of link wires LL may have a multilayer structure including various conductive materials.

For example, the plurality of link wires LL may have a triple-layer structure of titanium (Ti)/aluminum (Al)/titanium (Ti), but the embodiments of the present disclosure are not limited thereto.

The plurality of link wires LL may be formed in various shapes to reduce stress.

At least portions of the plurality of link wires LL positioned in the bending area BA may extend in the same direction as the extension direction of the bending area BA, or may extend in a direction different from the extension direction of the bending area BA to reduce stress. For example, when the bending area BA extends in one direction from the first non-display area NA1 toward the second non-display area NA2, at least portions of the link wires LL positioned in the bending area BA may extend in a direction inclined with respect to the one direction.

In another example, at least portions of the plurality of link wires LL may be formed in a pattern of various shapes. For example, at least portions of the plurality of link wires LL positioned in the bending area BA may have a configuration in which a conductive pattern having at least one of a diamond shape, a rhombus shape, a trapezoidal wave shape, a triangular wave shape, a sawtooth wave shape, a sine wave shape, a circular shape, and an omega (Ω) shape is repeatedly arranged. However, the embodiments of the present disclosure are not limited thereto.

Accordingly, in order to minimize stress concentrated in the plurality of link wire LL and cracks resulting therefrom, the plurality of link wires LL may be formed in various shapes including the above-described shapes, but the embodiments of the present disclosure are not limited thereto.

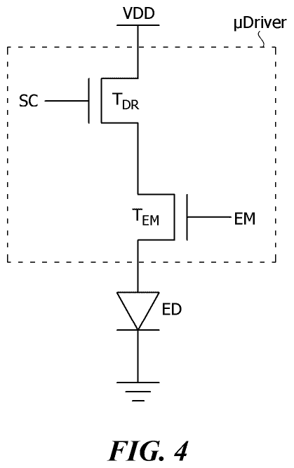

FIG. 4 is a diagram illustrating a circuit structure according to an embodiment of the present disclosure.

In FIG. 4, an example in which one light emitting element ED is connected to a micro driver μDriver is illustrated, but the embodiments of the present disclosure are not limited thereto. For example, eight light emitting elements ED may be connected to one micro driver μDriver. In another example, sixteen light emitting elements ED may be connected to one micro driver μDriver, or thirty-two light emitting elements ED, or sixty-four light emitting elements ED may be simultaneously connected to one micro driver μDriver. The light emitting element ED may be a micro light emitting element (μLED).

One micro driver μDriver may include a driving transistor T_{DR} and a light emitting transistor T_{EM}, but the embodiments of the present disclosure are not limited thereto.

For example, the first electrode of the driving transistor T_{DR} may receive a high potential power voltage VDD, the second electrode of the driving transistor T_{DR} may be connected to the first electrode of the light emitting transistor T_{EM}, and the gate electrode of the driving transistor T_{DR} may receive a scan signal SC. The scan signal SC applied to the gate electrode of the driving transistor T_{DR} may be a direct current (DC) power, and a fixed reference voltage (Vref) may be applied in each frame, but the embodiments of the present disclosure are not limited thereto.

The first electrode of the light emitting transistor T_{EM} may be connected to the second electrode of the driving transistor T_{DR}, the second electrode of the light emitting transistor T_{EM} may be connected to the light emitting element ED, and the gate electrode of the light emitting transistor T_{EM} may receive an emission signal EM. The emission signal EM applied to the gate electrode of the light emitting transistor T_{EM} may be a pulse width modulation signal that varies for each frame, but the embodiments of the present disclosure are not limited thereto.

The first electrode of the light emitting element ED may be connected to the second electrode of the light emitting transistor T_{EM} and the second electrode of the light emitting element ED may be connected to ground. For example, the first electrode may be an anode electrode and the second electrode may be a cathode electrode, but the embodiments of the present disclosure are not limited thereto.

Each of the driving transistor T_{DR} and the light emitting transistor T_{EM} may be an n-type transistor or a p-type transistor.

In the micro driver μDriver, the driving transistor T_{DR} may be turned on by the scan signal SC applied from the timing controller (T-COM), and the light emitting transistor T_{EM} may be turned on by the emission signal EM. As a result, a driving current may be applied to the light emitting element ED through the driving transistor T_{DR} and the light emitting transistor T_{EM} by the high potential power voltage VDD applied to the first electrode of the driving transistor T_{DR}, so that the light emitting element ED may emit light.

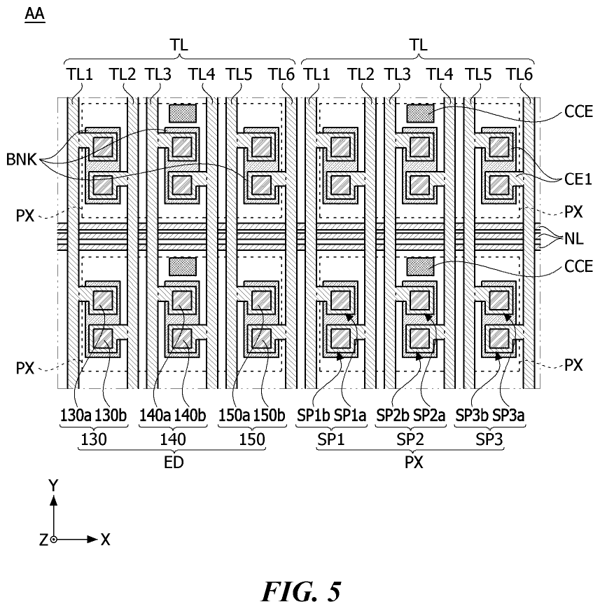

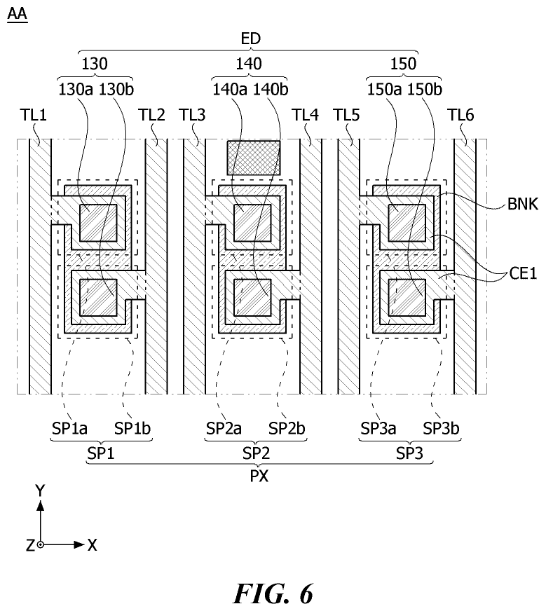

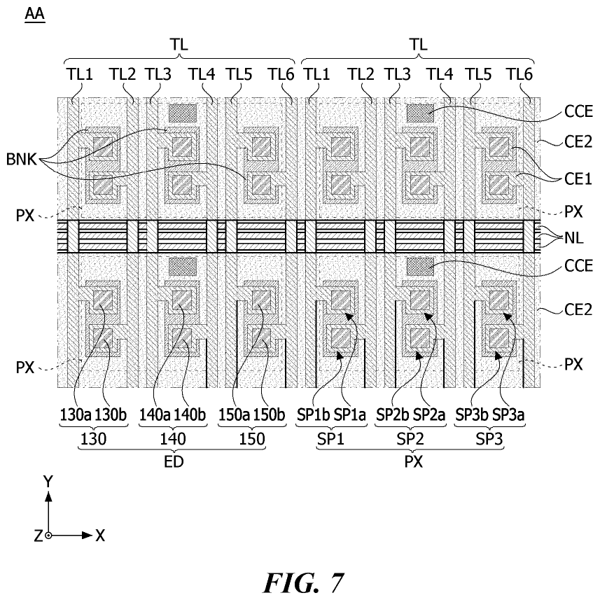

FIGS. 5 to 7 are plan views of a display device according to an embodiment of the present disclosure. For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels.

Although FIGS. 5 and 6 illustrate only a plurality of signal wires TL, a plurality of communication wires NL, a plurality of first electrodes CE1, a plurality of banks BNK, and the plurality of light emitting elements ED, the embodiments of the present disclosure are not limited thereto. FIG. 7 is an enlarged plan view in which a plurality of second electrodes CE2 are additionally arranged in the configuration of FIG. 5.

Referring to FIGS. 5 and 6, the plurality of pixels PX, each including a plurality of sub-pixels, may be arranged in the display area AA. Each of the plurality of sub-pixels includes the light emitting element ED and may independently emit light. The plurality of sub-pixels may be arranged in a matrix form with a plurality of rows and a plurality of columns, but the embodiments of the present disclosure are not limited thereto.

The plurality of sub-pixels may include a first sub-pixel SP1, a second sub-pixel SP2, and a third sub-pixel SP3. For example, among the first sub-pixel SP1, the second sub-pixel SP2, and the third sub-pixel SP3, one may be a red sub-pixel, another may be a green sub-pixel, and the remaining one may be a blue sub-pixel. The types of the plurality of sub-pixels are merely exemplary, and the embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may be composed of a firs-first sub-pixel SP1a and a first-second sub-pixel SP1b. The pair of second sub-pixels SP2 may be composed of a second-first sub-pixel SP2a and a second-second sub-pixel SP2b.

The pair of third sub-pixels SP3 may be composed of a third-first sub-pixel SP3a and a third-second sub-pixel SP3b. For example, one pixel PX may include the first-first sub-pixel SP1a and the first-second sub-pixel SP1b, the second-first sub-pixel SP2a, the second-second sub-pixel SP2b, the third-first sub-pixel SP3a, and the third-second sub-pixel SP3b, but the embodiments of the present disclosure are not limited thereto.

The plurality of sub-pixels constituting one pixel PX may be arranged in various ways. For example, in one pixel PX, the pair of first sub-pixels SP1 may be arranged in the same column, the pair of second sub-pixels SP2 may be arranged in the same column, and the pair of third sub-pixels SP3 may be arranged in the same column. The first sub-pixel SP1, the second sub-pixel SP2, and the third sub-pixel SP3 may be arranged in the same row. The number and arrangement of the plurality of sub-pixels constituting one pixel PX are merely exemplary, and the embodiments of the present disclosure are not limited thereto.

The plurality of signal wires TL may be arranged in a region between the plurality of sub-pixels. The plurality of signal wires TL may extend in a column direction between the plurality of sub-pixels. The plurality of signal wires TL may be wires for transmitting an anode voltage from the driving circuit chip PD to the plurality of sub-pixels. For example, the plurality of signal wires TL may be electrically connected to the plurality of driving circuit chips PD and the first electrodes CE1 of the plurality of sub-pixels.

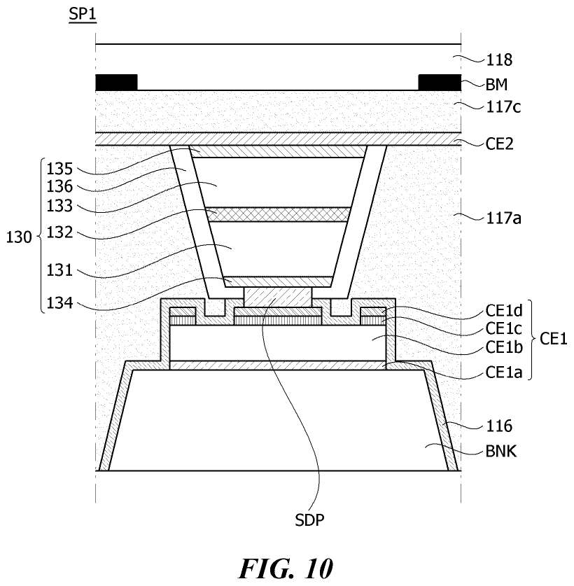

The anode voltage outputted from the driving circuit chip PD may be transmitted to the first electrodes CE1 of the plurality of sub-pixels through the plurality of signal wires TL. For example, the first electrode CE1 may be an electrode electrically connected to an anode electrode 134 (see FIG. 10) of the light emitting element ED. Accordingly, the anode voltage from the signal wire TL may be transmitted to the anode electrode 134 of the light emitting element ED through the first electrode CE1.

Therefore, instead of forming a plurality of transistors and storage capacitors in each of the plurality of sub-pixels, the driving circuit chip PD in which a plurality of pixel circuits are integrated may be used to simplify the structure of the display device 1000. Additionally, as circuits respectively positioned in the plurality of sub-pixels are integrated into one driving circuit chip PD, high-efficiency and low-power driving may be achieved.

The plurality of signal wires TL may include a first signal wire TL1, a second signal wire TL2, a third signal wire TL3, a fourth signal wire TL4, a fifth signal wire TL5 and a sixth signal wire TL6. The first signal wire TL1 and the second signal wire TL2 may be electrically connected to the pair of first sub-pixels SP1, respectively. The third signal wire TL3 and the fourth signal wire TL4 may be electrically connected to the pair of second sub-pixels SP2, respectively. The fifth signal wire TL5 and the sixth signal wire TL6 may be electrically connected to the pair of third sub-pixels SP3, respectively.

The first signal wire TL1 may be positioned on one side of the pair of first sub-pixels SP1, and the second signal wire TL2 may be positioned on the other side of the pair of first sub-pixels SP1. The first signal wire TL1 may be electrically connected to the first electrode CE1 of one, e.g., the first-first sub-pixel SP1a, of the pair of first sub-pixels SP1. The second signal wire TL2 may be electrically connected to the first electrode CE1 of the other, e.g., the first-second sub-pixel SP1b, of the pair of first sub-pixels SP1.

The third signal wire TL3 may be positioned on one side of the pair of second sub-pixels SP2, and the fourth signal wire TL4 may be positioned on the other side of the pair of second sub-pixels SP2. For example, the third signal wire TL3 may be positioned adjacent to the second signal wire TL2. The third signal wire TL3 may be electrically connected to the first electrode CE1 of one, e.g., the second-first sub-pixel SP2a, of the pair of second sub-pixels SP2. The fourth signal wire TL4 may be electrically connected to the first electrode CE1 of the other, e.g., the second-second sub-pixel SP2b, of the pair of second sub-pixels SP2.

The fifth signal wire TL5 may be positioned on one side of the pair of third sub-pixels SP3, and the sixth signal wire TL6 may be positioned on the other side of the pair of third sub-pixels SP3. For example, the fifth signal wire TL5 may be positioned adjacent to the fourth signal wire TL4. The sixth signal wire TL6 may be positioned adjacent to the first signal wire TL1 that is connected to an adjacent pixel PX. The fifth signal wire TL5 may be electrically connected to the first electrode CE1 of one, e.g., the third-first sub-pixel SP3a, of the pair of third sub-pixels SP3. The sixth signal wire TL6 may be electrically connected to the first electrode CE1 of the other, e.g., the third-second sub-pixel SP3b, of the pair of third sub-pixels SP3.

The plurality of signal wires TL may be formed of a conductive material. For example, the plurality of signal wires TL may be formed of a conductive material, such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present disclosure are not limited thereto. In another example, the plurality of signal wires TL may have a multilayer structure of a conductive material. For example, the plurality of signal wires TL may have a multilayer structure of titanium (Ti)/aluminum (Al)/titanium (Ti)/indium tin oxide (ITO), but the embodiments of the present disclosure are not limited thereto.

The plurality of communication wires NL may be arranged in a region between the plurality of pixels PX. The plurality of communication wires NL may extend in a row direction in the region between the plurality of pixels PX. The plurality of communication wires NL may be positioned in a region between the plurality of second electrodes CE2, and may not overlap the plurality of second electrodes CE2. For example, the plurality of communication wires NL may be wires used for short-range communication, such as near field communication (NFC). The plurality of communication wires NL may function as an antenna. For example, the plurality of communication wires NL may be a plurality of connection wires or the like, but the embodiments of the present disclosure are not limited thereto.

According to the present disclosure, the bank BNK may be positioned in each of the plurality of sub-pixels. The plurality of banks may be structures on which the plurality of light emitting elements are mounted. In a transfer process for transferring the plurality of light emitting elements ED to the display device 1000, the plurality of banks may guide the positions of the plurality of light emitting elements ED. During the transfer process of the plurality of light emitting elements ED, the plurality of light emitting elements ED may be transferred onto the plurality of banks BNK. The plurality of banks BNK may be bank patterns or structures, but the embodiments of present disclosure are not limited thereto.

The bank BNK of the first sub-pixel SP1, the bank BNK of the second sub-pixel SP2, and the bank BNK of the third sub-pixel SP3 may be spaced apart from each other. The bank BNK of the first sub-pixel SP1, the bank BNK of the second sub-pixel SP2, and the bank BNK of the third sub-pixel SP3 may be configured to be separated from each other. Accordingly, the banks BNK of the first sub-pixel SP1, the second sub-pixel SP2, and the third sub-pixel SP3, onto which different types of light emitting elements ED are transferred, may be easily distinguished.

The bank BNK of the first-first sub-pixel SP1a and the bank BNK of the first-second sub-pixel SP1b may be connected to each other, or may be spaced apart from each other or formed separately. For example, the banks BNK of the first-first sub-pixel SP1a and the first-second sub-pixel SP1b, in which the same type of light emitting elements ED are positioned, may be connected to each other or may be spaced apart or separated from each other in consideration of design factors such as requirements for the transfer process. In addition, the bank BNK of the second-first sub-pixel SP2a and the bank BNK of the second-second sub-pixel SP2b may be connected to each other or may be spaced apart or separately formed. The bank BNK of the third-first sub-pixel SP3a and the bank BNK of the third-second sub-pixel SP3b may also be connected to each other, or may be spaced apart from each other or formed separately. Accordingly, the banks BNK of the pair of first sub-pixels SP1, the pair of second sub-pixels SP2, and the pair of third sub-pixels SP3 may be formed in various configurations, and the embodiments of the present disclosure are not limited thereto.

For example, the plurality of banks BNK may be formed of an organic insulating material. The plurality of banks BNK may be composed of a single layer or multiple layers of the organic insulating material. For example, the plurality of banks BNK may be formed of a photoresist, polyimide (PI), or acryl-based material, but the embodiments of present disclosure are not limited thereto.

The first electrode CE1 may be positioned in each of the plurality of sub-pixels. The first electrode CE1 may be positioned on the bank BNK. The first electrode CE1 may be electrically connected to one of the plurality of signal wires TL. At least a portion of the first electrode CE1 may extend outside the bank BNK and be electrically connected to the signal wire TL closest to the first electrode CE1. For example, a portion of the first electrode CE1 of the first-first sub-pixel SP1a may extend to one side region of the first-first sub-pixel SP1a and be electrically connected to the first signal wire TL1, and a portion of the first electrode CE1 of the first-second sub-pixel SP1b may extend to the other side region of the first-second sub-pixel SP1b and be electrically connected to the second signal wire TL2. A portion of the first electrode CE1 of the second-first sub-pixel SP2a may extend to one side region of the second-first sub-pixel SP2a and be electrically connected to the third signal wire TL3, and a portion of the first electrode CE1 of the second-second sub-pixel SP2b may extend to the other side region of the second-second sub-pixel SP2b and be electrically connected to the fourth signal wire TL4. A portion of the first electrode CE1 of the third-first sub-pixel SP3a may extend to one side region of the third-first sub-pixel SP3a and be electrically connected to the fifth signal wire TL5, and a portion of the first electrode CE1 of the third-second sub-pixel SP3b may extend to the other side region of the third-second sub-pixel SP3b and be electrically connected to the sixth signal wire TL6.

The first electrode CE1 may be electrically connected to the anode electrode 134 of the light emitting element ED, and may transmit an anode voltage from the driving circuit chip PD to the light emitting element ED through the signal wire TL. Different voltages may be applied to the first electrodes CE1 of the respective sub-pixels depending on an image to be displayed. For example, different voltages may be applied to the first electrodes CE1 of the respective sub-pixels. Accordingly, the first electrode CE1 may be a pixel electrode, and the embodiments of the present disclosure are not limited thereto.

The first electrode CE1 may be formed of a conductive material. For example, the first electrode CE1 may be integrally formed with the plurality of signal wires TL. For example, the first electrode CE1 may be formed of the same conductive material as the plurality of signal wires TL, but the embodiments of the present disclosure are not limited thereto. For example, the first electrode CE1 may be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present disclosure are not limited thereto. In another example, the first electrode CE1 may have a multilayer structure of a conductive material. For example, the plurality of first electrodes CE1 may have a multilayer structure of titanium (Ti)/aluminum (Al)/titanium (Ti)/indium tin oxide (ITO), but the embodiments of the present disclosure are not limited thereto.

The light emitting element ED may be positioned in each of the plurality of sub-pixels. The plurality of light emitting elements ED may be either light emitting diodes (LEDs) or micro light emitting diodes (micro LEDs), but the embodiments of the present disclosure are not limited thereto. The plurality of light emitting elements ED may be positioned on the bank BNK and the first electrode CE1. The light emitting elements ED may be positioned on the first electrode CE1 and electrically connected to the first electrode CE1. Accordingly, the light emitting element ED may emit light by receiving an anode voltage from the driving circuit chip PD through the signal wire TL and the first electrode CE1.

The plurality of light emitting elements ED may include a first light emitting element 130, a second light emitting element 140, and a third light emitting element 150. The first light emitting element 130 may be positioned in the first sub-pixel SP1. The second light emitting element 140 may be positioned in the second sub-pixel SP2. The third light emitting element 150 may be positioned in the third sub-pixel SP3. For example, one of the first light emitting element 130, the second light emitting element 140, and the third light emitting element 150 may be a red light emitting element, another one may be a green light emitting element, and the remaining one may be a blue light emitting element, but the embodiments of the present disclosure are not limited thereto. Accordingly, by combining red light, green light, and blue light emitted from the plurality of light emitting elements ED, light of various colors including white may be implemented. The types of the plurality of light emitting elements ED are merely exemplary, and the embodiments of the present disclosure are not limited thereto.

The first light emitting element 130 may include a first-first light emitting element 130a positioned in the first-first sub-pixel SP1a and a first-second light emitting element 130b positioned in the first-second sub-pixel SP1b. The second light emitting element 140 may include a second-first light emitting element 140a positioned in the second-first sub-pixel SP2a and a second-second light emitting element 140b positioned in the second-second sub-pixel SP2b. The third light emitting element 150 may include a third-first light emitting element 150a positioned in the third-first sub-pixel SP3a and a third-second light emitting element 150b positioned in the third-second sub-pixel SP3b.

Referring to FIGS. 5 and 6 together with FIG. 7, the second electrode CE2 may be positioned in each of the plurality of sub-pixels. The second electrode CE2 may be positioned on the light emitting element ED. The second electrode CE2 may be electrically connected to the driving circuit chip PD through a plurality of contact electrodes CCE.

For example, the second electrode CE2 may be electrically connected to a cathode electrode 135 of the light emitting element ED and may transmit a cathode voltage from the driving circuit chip PD to the light emitting element ED. The same cathode voltage may be applied to the second electrode CE2 of each of the plurality of sub-pixels. For example, the same voltage may be applied to the second electrode CE2 of each of the plurality of sub-pixels and the cathode electrode 135 of the light emitting element ED. Accordingly, the second electrode CE2 may be a common electrode, but the embodiments of the present disclosure are not limited thereto.

At least some of the plurality of sub-pixels may share the second electrode CE2. At least some of the second electrodes CE2 of the plurality of sub-pixels may be electrically connected to each other. As the same voltage is applied to the second electrodes CE2, the second electrodes CE2 of at least some sub-pixels may be shared. For example, the second electrodes CE2 of at least some of the plurality of pixels PX arranged in the same row may be connected to each other. For example, one second electrode CE2 may be provided for the plurality of pixels PX. One second electrode CE2 may be provided for every n sub-pixels.

For example, some of the second electrodes CE2 of the plurality of sub-pixels may be spaced apart or separated from each other. For example, the second electrode CE2 connected to the pixels PX in an n^{th} row and the second electrode CE2 connected to the pixels PX in an (n+1)^{th} row may be spaced apart or separated from each other. For example, the plurality of second electrodes CE2 may be spaced apart from each other with the plurality of communication wires NL, which extend in the row direction, interposed therebetween. Accordingly, the number of the sub-pixels may be greater than the number of the second electrodes CE2. In another example, all of the second electrodes CE2 of the plurality of sub-pixels may be electrically connected to each other, so that only one second electrode CE2 may be positioned on the substrate 110, but the embodiments of the present disclosure are not limited thereto.

The plurality of second electrodes CE2 may be formed of a transparent conductive material, but the embodiments of the present disclosure are not limited thereto. The plurality of second electrodes CE2 may be formed of a transparent conductive material, allowing light emitted from the light emitting element ED to be directed upward through the second electrode CE2. For example, the second electrode CE2 may be formed of a transparent conductive material such as indium tin oxide (ITO), indium zinc oxide (IZO), or indium gallium zinc oxide (IGZO), but the embodiments of the present disclosure are not limited thereto.

The plurality of contact electrodes CCE may be arranged on the substrate 110. For example, the plurality of contact electrodes CCE may be spaced apart from the plurality of banks BNK and the plurality of signal wires TL. Each of the plurality of second electrodes CE2 may overlap at least one contact electrode CCE. For example, one second electrode CE2 may overlap multiple contact electrodes CCE.

For example, the plurality of contact electrodes CCE may be electrically connected to the plurality of second electrodes CE2. The plurality of contact electrodes CCE may be positioned between the substrate 110 and the plurality of second electrodes CE2 and may transmit a cathode voltage from the driving circuit chip PD to the second electrodes CE2.

For example, when using a micro LED as the light emitting element ED, a plurality of micro LEDs may be formed on a wafer and transferred to the substrate 110 of the display device 1000 to fabricate the display device 1000. In the process of transferring the plurality of light emitting elements ED having a fine size from the wafer to the substrate 110, various defects may occur. For example, in some sub-pixels, a transfer failure may occur where the light emitting element ED is not transferred, and in some other sub-pixels, a defect may occur where the light emitting element ED is transferred to an incorrect position due to an alignment error. Additionally, even if the transfer process is normally performed, the transferred light emitting element ED itself may be defective. Therefore, in the transfer process of the plurality of light emitting elements ED, in consideration of defects, a plurality of light emitting elements ED of the same type may be transferred onto one sub-pixel. A lighting test may be performed on the plurality of light emitting elements ED and only one light emitting element ED that is finally determined to be normal may be used.

For example, the first-first light emitting element 130a and the first-second light emitting element 130b may be transferred together onto one pixel PX, and their defect states may be inspected. If both the first-first light emitting element 130a and the first-second light emitting element 130b are determined to be normal, only the first-first light emitting element 130a may be used and the first-second light emitting element 130b may remain unused. In another example, if, among the first-first light emitting element 130a and the first-second light emitting element 130b, only the first-second light emitting element 130b is determined to be normal, the first-first light emitting element 130a may remain unused and only the first-second light emitting element 130b may be used. Accordingly, even when a plurality of light emitting elements ED of the same type are transferred onto one pixel PX, only one of the light emitting elements ED may be ultimately used.

Therefore, in a pair of the light emitting elements ED, one may be a main (or primary) light emitting element ED, while the other may be a redundancy light emitting element ED. The redundancy light emitting element ED may be an extra light emitting element ED that is transferred in preparation for a defect in the main light emitting element ED. The redundant light emitting element may be used as a replacement in the event of a failure of the main light emitting element. Accordingly, the main light emitting element ED and the redundancy light emitting element ED may be transferred together onto one pixel PX, thereby minimizing degradation in display quality caused by defects in the main light emitting element ED or the redundancy light emitting element ED.

For example, the first-first light emitting element 130a, the second-first light emitting element 140a, and the third-first light emitting element 150a, which are transferred to one pixel PX, may be used as the main light emitting elements ED, and the first-second light emitting element 130b, the second-second light emitting element 140b, and the third-second light emitting element 150b may be used as the redundant light emitting elements ED.

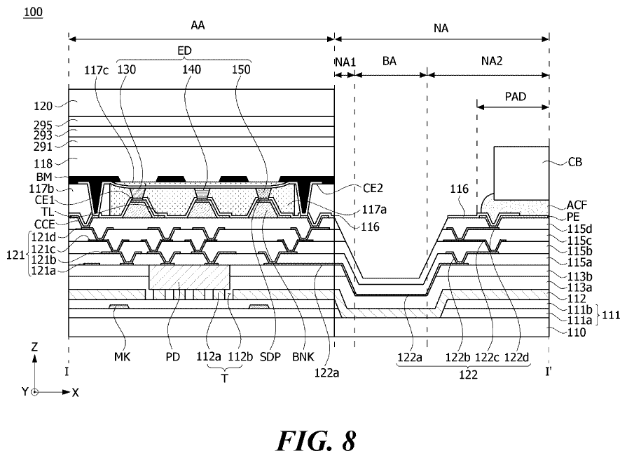

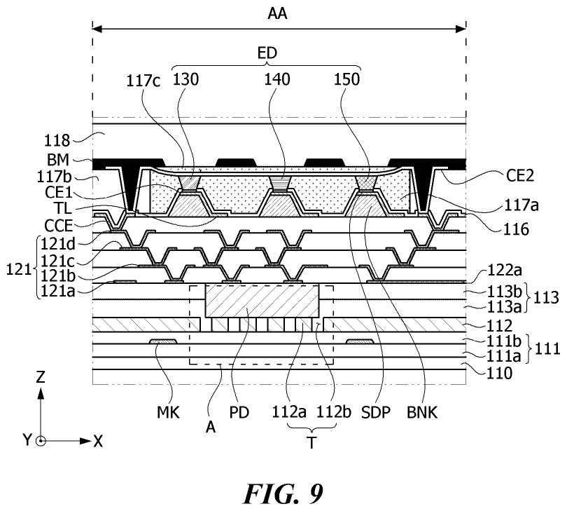

FIG. 8 is a cross-sectional view taken along line I-I′ in FIG. 3. FIG. 9 is an enlarged cross-sectional view of a display device according to an embodiment of the present disclosure. FIG. 10 is an enlarged cross-sectional view of a display device according to an embodiment of the present disclosure. For example, FIG. 8 is a cross-sectional view of the display area AA, the first and second non-display areas NA1 and NA2, and the bending area BA. FIG. 9 is an enlarged cross-sectional view of the display area AA of the display device.

Referring to FIGS. 8 and 9, a buffer layer 111 may be positioned in the remaining areas of the substrate 110 excluding the bending area BA, e.g., in the display area AA and the non-display area NA. The buffer layer 111 may include a first buffer layer 111a and a second buffer layer 111b.

The first buffer layer 111a and the second buffer layer 111b may be positioned in the display area AA, but may not be positioned in the first non-display area NA1 and the second non-display area NA2. However, the embodiments of the present disclosure are not limited thereto. The first buffer layer 111a and the second buffer layer 111b may reduce the permeation of moisture or impurities through the substrate 110. The first buffer layer 111a and the second buffer layer 111b may be formed of an inorganic insulating material. For example, the first buffer layer 111a and the second buffer layer 111b may be composed of a single layer or multiple layers of silicon oxide (SiOx) or silicon nitride (SiNx), but the embodiments of the present disclosure are not limited thereto. In order to prevent moisture permeation from the non-display area NA, the buffer layer 111 may be positioned only in the display area AA. However, the embodiments of the present disclosure are not limited thereto. The non-display area NA may include the first non-display area NA1, the bending area BA, and the second non-display area NA2. The buffer layer 111 may be composed of a single layer or multiple layers of silicon oxide (SiOx) or silicon nitride (SiNx), which is an inorganic film material, but the embodiments of the present disclosure are not limited thereto. For example, portions of the first buffer layer 111a and the second buffer layer 111b in the bending area BA may be removed. The top surface of the substrate 110 positioned in the bending area BA may be exposed from the first buffer layer 111a and the second buffer layer 111b. By removing the first buffer layer 111a and the second buffer layer 111b made of an inorganic insulating material from the bending area BA, cracks that may occur in the first buffer layer 111a and the second buffer layer 111b during bending may be minimized.

A plurality of alignment keys MK may be arranged between the first buffer layer 111a and the second buffer layer 111b. The plurality of alignment keys MK may be configured to identify the position of the driving circuit chip PD during the fabricating process of the display device 1000. For example, the plurality of alignment keys MK may be configured to align the position of the driving circuit chip PD transferred onto an adhesive layer 112. In another example, the plurality of alignment keys MK may be omitted. However, the embodiments of the present disclosure are not limited thereto.

The adhesive layer 112 may be positioned on the second buffer layer 111b. The adhesive layer 112 may be positioned in the display area AA, the first non-display area NA1, the bending area BA, and the second non-display area NA2. In another example, at least a portion of the adhesive layer 112 may be removed from the non-display area NA including the bending area BA. For example, the adhesive layer 112 may be formed of any one of an adhesive polymer, an epoxy resin, a UV-curable resin, a polyimide-based material, an acrylate-based material, a urethane-based material, and polydimethylsiloxane (PDMS), but the embodiments of the present disclosure are not limited thereto.

The adhesive layer 112 may be provided with a driving circuit chip transfer portion T to which the driving circuit chip PD is transferred and bonded. The driving circuit chip transfer portion T may include a plurality of support patterns 112a spaced apart from each other such that the driving circuit chip PD is transferred and supported. In addition, a pass hole 112b, e.g., a bubble path may be provided between the support patterns 112a spaced apart from each other. The pass holes 112b formed between the plurality of support patterns 112a may communicate with each other and be exposed to the outside. However, the present disclosure is not limited thereto. Accordingly, by forming the pass hole 112b together with the plurality of support patterns 112a in the driving circuit chip transfer portion T of the adhesive layer 112, foreign particles P may be discharged to the outside, thereby reducing the likelihood that the foreign particles remain on the surface of the adhesive layer 112 including the plurality of support patterns 112a. As a result, the transfer yield of the driving circuit chip during the fabrication of the display device may be increased.

After the driving circuit chip PD is transferred, during a curing process of the adhesive layer 112, not only bubbles B present in the adhesive layer 112 but also bubbles B present in the support patterns 112a may be discharged to the outside through the pass hole 112b. For example, during the curing process of the adhesive layer 112, residual solvent in the adhesive layer 112, e.g., a trapped big void may be removed.

In the display area AA, the driving circuit chip PD may be positioned on the adhesive layer 112. For example, the driving circuit chip PD may be positioned on the driving circuit chip transfer portion T of the adhesive layer 112. When the driving circuit chip PD is implemented as a driving driver, the driving driver may be mounted on the adhesive layer 112 through a transfer process, but the embodiments of the present disclosure are not limited thereto.

A first planarization layer 113a and a second planarization layer 113b may be positioned on the adhesive layer 112 and the driving circuit chip PD. The first planarization layer 113a and the second planarization layer 113b may be positioned to surround the side surface of the driving circuit chip PD, but the embodiments of the present disclosure are not limited thereto. For example, the second planarization layer 113b may be positioned to cover at least a portion of the top surface of the driving circuit chip PD. For example, at least one of the first planarization layer 113a and the second planarization layer 113b positioned in the bending area BA may be omitted. For example, the first planarization layer 113a may be entirely positioned in the display area AA and the non-display area NA, and the second planarization layer 113b may be partially positioned in the display area AA, the first non-display area NA1, and the second non-display area NA2. For example, a portion of the second planarization layer 113b in the bending area BA may be removed. However, the embodiments of the present disclosure are not limited thereto.

The first planarization layer 113a and the second planarization layer 113b may be formed of an organic insulating material, but the embodiments of the present disclosure are not limited thereto. For example, the first planarization layer 113a and the second planarization layer 113b may be formed of photoresist, polyimide (PI), or a photoacryl-based material, but the embodiments of the present disclosure are not limited thereto. For example, the first planarization layer 113a and the second planarization layer 113b may be an overcoat layer or an insulating layer, but the embodiments of the present disclosure are not limited thereto.

According to the present disclosure, a plurality of first connection wires 121 may be arranged on the second planarization layer 113b in the display area AA. The plurality of first connection wires 121 may be wires for electrically connecting the driving circuit chip PD to other components. For example, the driving circuit chip PD may be electrically connected to the plurality of signal wires TL, the plurality of contact electrodes CCE, and the like through the plurality of first connection wires 121. For example, the plurality of first connection wires 121 may include a first-first connection wire 121a, a first-second connection wire 121b, a first-third connection wire 121c, and a first-fourth connection wire 121d, but the embodiments of the present disclosure are not limited thereto.

For example, the plurality of first-first connection wires 121a may be positioned on the second planarization layer 113b. The plurality of first-first connection wires 121a may be electrically connected to the driving circuit chip PD. The plurality of first-first connection wires 121a may transmit a voltage outputted from the driving circuit chip PD to the first electrode CE1 or the second electrode CE2.

For example, the first and second planarization layers 113a and 113b may be formed of an organic insulating material. For example, the first and second planarization layers 113a and 113b may be formed of photoresist, polyimide (PI), or photo-acryl-based material, but the embodiments of the present disclosure are not limited thereto. For example, the first planarization layer 113a and the second planarization layer 113b may be formed of the same material, but the embodiments of the present disclosure are not limited thereto.

A first organic insulating layer 115a may be positioned on the second planarization layer 113b. The first organic insulating layer 115a may be formed of an organic insulating material, but the embodiments of the present disclosure are not limited thereto. For example, the first organic insulating layer 115a may be formed of a photoresist, polyimide (PI), or a photoacryl-based material, but the embodiments of the present disclosure are not limited thereto.

The plurality of first-second connection wires 121b may be positioned on the first organic insulating layer 115a. A plurality of the first-second connection wires 121b may be connected to or directly connected to the driving circuit chip PD. For example, a portion of the first-second connection wire 121b may be directly connected to the driving circuit chip PD through a contact hole of the first insulating layer (not shown). Another portion of the first-second connection wire 121b may be electrically connected to the first-first connection wire 121a through a contact hole of the first insulating layer (not shown). However, the embodiments of the present disclosure are not limited thereto. A voltage outputted from the driving circuit chip PD may be transmitted to the first electrode CE1 or the second electrode CE2 through the plurality of first-second connection wires 121b and other connection wires.

A second organic insulating layer 115b may be positioned on the plurality of first-second connection wires 121b. The second organic insulating layer 115b may be entirely positioned in the display area AA and the non-display area NA, but the embodiments of the present disclosure are not limited thereto. The second organic insulating layer 115b may be formed of an organic insulating material, but the embodiments of the present disclosure are not limited thereto. For example, the second organic insulating layer 115b may be formed of photoresist, polyimide (PI), or a photo-acryl-based material, but the embodiments of the present disclosure are not limited thereto.

The plurality of first-third connection wires 121c may be positioned on the second organic insulating layer 115b. The plurality of first-third connection wires 121c may be electrically connected to the plurality of first-second connection wires 121b. For example, the first-third connection wire 121c may be electrically connected to the first-second connection wire 121b through a contact hole of the second organic insulating layer 115b.

A third organic insulating layer 115c may be positioned on the plurality of first-third connection wires 121c. The third organic insulating layer 115c may be positioned in the remaining areas excluding the bending area BA, but the embodiments of the present disclosure are not limited thereto. The third organic insulating layer 115c may be positioned in the display area AA, the first non-display area NA1, and the second non-display area NA2, but the embodiments of the present disclosure are not limited thereto. For example, a portion of the third organic insulating layer 115c positioned in the bending area BA may be removed. The third organic insulating layer 115c may be formed of an organic insulating material, but the embodiments of the present disclosure are not limited thereto. For example, the third organic insulating layer 115c may be formed of photoresist, polyimide (PI), or photoacryl-based material, but the embodiments of the present disclosure are not limited thereto.

The plurality of first-fourth connection wires 121d may be positioned on the third organic insulating layer 115c. The plurality of first-fourth connection wires 121d may be electrically connected to the plurality of first-third connection wires 121c. For example, the first-fourth connection wire 121d may be electrically connected to the first-third connection wire 121c through a contact hole of the third organic insulating layer 115c.

A fourth organic insulating layer 115d may be positioned on the plurality of first-fourth connection wires 121d. The fourth organic insulating layer 115d may be positioned in the remaining areas excluding the bending area BA, but the embodiments of the present disclosure are not limited thereto. The fourth organic insulating layer 115d may be positioned in the display area AA, the first non-display area NA1, and the second non-display area NA2, but the embodiments of the present disclosure are not limited thereto.

According to the present disclosure, a plurality of second connection wires 122 may be positioned on the second planarization layer 113b in the non-display area NA. The plurality of second connection wires 122 may be wires for transmitting a signal, which has been transmitted to the pad portion PAD from the flexible circuit board (or flexible film) CB and the printed circuit board 160 (see FIG. 1), to the driving circuit chip PD of the display area AA. For example, the plurality of second connection wires 122 may be electrically connected to the plurality of pad electrodes PE to receive a signal from the flexible circuit board (or flexible film) CB and the printed circuit board 160.

A plurality of second-first connection wires 122a may be positioned on the second planarization layer 113b. The plurality of second-first connection wires 122a may extend from the second non-display area NA2 to the bending area BA and the first non-display area NA1. The plurality of second-first connection wires 122a may transmit a signal, which has been transmitted to the pad portion PAD from the flexible circuit board (or flexible film) CB and the printed circuit board 160 (see FIG. 1), to the driving circuit chip PD of the display area AA.

A plurality of second-second connection wires 122b may be positioned on the first insulating layer (not shown) and the first organic insulating layer 115a. The plurality of second-second connection wires 122b may be positioned in the second non-display area NA2. The second-second connection wire 122b may be electrically connected to the second-first connection wire 122a through a contact hole of the first insulating layer. Accordingly, a signal from the flexible circuit board (or flexible film) CB and the printed circuit board 160 may be transmitted to the second-first connection wire 122a through the second-second connection wire 122b.

A second-third connection wire 122c may be positioned on the second organic insulating layer 115b. The second-third connection wire 122c may be positioned in the second non-display area NA2. The second-third connection wire 122c may be electrically connected to the second-second connection wire 122b through a contact hole of the second organic insulating layer 115b. Accordingly, a signal from the flexible circuit board (or flexible film) CB and the printed circuit board 160 may be transmitted to the second-first connection wire 122a through the second-third connection wire 122c and the second-second connection wire 122b.

The third organic insulating layer 115c may be positioned on the second organic insulating layer 115b and the second-third connection wire 122c. A second-fourth connection wire 122d may be positioned on the third organic insulating layer 115c. The second-fourth connection wire 122d may be positioned in the second non-display area NA2. The second-fourth connection wire 122d may be electrically connected to the second-third connection wire 122c through a contact hole of the third organic insulating layer 115c. Accordingly, a signal from the flexible film CB and the printed circuit board 160 may be transmitted to the second-first connection wire 122a through the second-fourth connection wire 122d, the second-third connection wire 122c, and the second-second connection wire 122b.

The plurality of first connection wires 121 and the plurality of second connection wires 122 may be formed of a conductive material having excellent flexibility or any one of various conductive materials used in the display area AA. For example, the second connection wire 122, a portion of which is positioned in the bending area BA, may be formed of a conductive material having excellent flexibility, such as gold (Au), silver (Ag), or aluminum (Al), but the embodiments of the present disclosure are not limited thereto. In another example, the plurality of first connection wires 121 and the plurality of second connection wires 122 may be formed of molybdenum (Mo), chromium (Cr), titanium (Ti), nickel (Ni), neodymium (Nd), copper (Cu), an alloy of silver (Ag) and magnesium (Mg), or another alloy thereof, but the embodiments of the present disclosure are not limited thereto.

The fourth organic insulating layer 115d may be positioned on the plurality of first connection wires 121 and the plurality of second connection wires 122. The fourth organic insulating layer 115d may be positioned in the remaining areas excluding the bending area BA, but the embodiments of the present disclosure are not limited thereto. The third organic insulating layer 115c may be positioned in the display area AA, the first non-display area NA1, and the second non-display area NA2. A portion of the third organic insulating layer 115c in the bending area BA may be removed. The fourth organic insulating layer 115d may be formed of an organic insulating material, but the embodiments of the present disclosure are not limited thereto. For example, the fourth organic insulating layer 115d may be formed of a photoresist, polyimide (PI), or photo acryl-based material, but the embodiments of the present disclosure are not limited thereto.

Referring to FIGS. 8 and 9, the plurality of banks BNK may be positioned on the fourth organic insulating layer 115d in the display area AA. The plurality of banks BNK may be positioned to respectively overlap the sub-pixels. One or more light emitting elements ED of the same type may be positioned on each of the plurality of banks BNK.

The plurality of signal wires TL may be positioned on the fourth organic insulating layer 115d in the display area AA. The plurality of signal wires TL may be positioned in regions between the plurality of banks BNK. For example, the plurality of signal wires TL may be positioned adjacent to any one of the plurality of banks BNK.

The plurality of contact electrodes CCE may be positioned on the fourth organic insulating layer 115d in the display area AA. The plurality of contact electrodes CCE may supply a cathode voltage from the driving circuit chip PD to the second electrode CE2.

The first electrode CE1 may be positioned on the bank BNK. For example, the first electrode CE1 may extend from an adjacent signal wire TL toward the top of the bank BNK. The first electrode CE1 may be positioned on the top and side surfaces of the bank BNK. For example, the first electrode CE1 may extend from the signal wire TL on the top surface of the fourth organic insulating layer 115d to the side surface of the bank BNK and to the top surface of the bank BNK.

Referring to FIG. 10, the first electrode CE1 may be composed of a plurality of conductive layers. For example, the first electrode CE1 may include a first conductive layer CE1a, a second conductive layer CE1b, a third conductive layer CE1c, and a fourth conductive layer CE1d, but the embodiments of the present disclosure are not limited thereto.

The first conductive layer CE1a may be positioned on the bank BNK. The second conductive layer CE1b may be positioned on the first conductive layer CE1a. The third conductive layer CE1c may be positioned on the second conductive layer CE1b. The fourth conductive layer CE1d may be positioned on the third conductive layer CE1c. For example, each of the first conductive layer CE1a, the second conductive layer CE1b, the third conductive layer CE1c, and the fourth conductive layer CE1d may be formed of titanium (Ti), molybdenum (Mo), aluminum (Al), or titanium (Ti) and indium tin oxide (ITO), but the embodiments of the present disclosure are not limited thereto.

According to the present disclosure, among the plurality of conductive layers constituting the first electrode CE1, some conductive layers with high reflection efficiency may be configured as an alignment key and/or a reflective plate for aligning the light emitting element ED. For example, among the plurality of conductive layers of the first electrode CE1, the second conductive layer CE1b may include a reflective material. For example, the second conductive layer CE1b may include aluminum (Al), but the embodiments of the present disclosure are not limited thereto. Accordingly, the second conductive layer CE1b may configured as a reflective plate. In addition, due to the high reflection efficiency of the second conductive layer CE1b, the second conductive layer CE1b may be easily identified during the fabricating process, and thus the position or transfer position of the light emitting element ED may be aligned based on the second conductive layer CE1b.

For example, in order to configure the second conductive layer CE1b as a reflective plate, the third conductive layer CE1c and the fourth conductive layer CE1d covering the second conductive layer CE1b may be partially removed or etched. For example, portions of the third conductive layer CE1c and the fourth conductive layer CE1d positioned on the bank BNK may be removed or etched to expose the top surface of the second conductive layer CE1b. For example, in the third conductive layer CE1c and the fourth conductive layer CE1d, a central portion where a solder pattern SDP is positioned and an edge portion (or peripheral portion) may be left, while the remaining portions may be removed. For example, the edge portion (or peripheral portion) of each of the third conductive layer CE1c made of titanium (Ti) and the fourth conductive layer CE1d made of indium tin oxide (ITO) may not be etched. Accordingly, it is possible to prevent other conductive layers of the first electrode CE1 from being corroded by a tetramethylammonium hydroxide (TMAH) solution used in the mask process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has good adhesion to the solder pattern SDP and exhibits corrosion resistance and acid resistance. However, the embodiments of the present disclosure are not limited thereto.

The first conductive layer CE1a, the second conductive layer CE1b, the third conductive layer CE1c, and the fourth conductive layer CE1d may be sequentially deposited, and then may be patterned by performing a photolithography process and an etching process, but the embodiments of the present disclosure are not limited thereto.

According to the present disclosure, the signal wire TL, the contact electrode CCE, and the pad electrode PE positioned in the same layer as the first electrode CE1 may be formed as multiple layers of a conductive material, but the embodiments of the present disclosure are not limited thereto. For example, the signal wire TL, the contact electrode CCE, and the pad electrode PE may be formed as multiple layers of indium tin oxide (ITO)/titanium (Ti)/aluminum (Al)/titanium (Ti), but the embodiments of the present disclosure are not limited thereto.

According to the present disclosure, the solder pattern SDP may be positioned on the first electrode CE1 in each of the plurality of sub-pixels. The solder pattern SDP may bond the first electrode CE1 to the light emitting element ED. The first electrode CE1 and the light emitting element ED may be electrically connected to each other through eutectic bonding using the solder pattern SDP, but the embodiments of the present disclosure are not limited thereto. For example, when the solder pattern SDP is made of indium (In), and the anode electrode 134 of the light emitting element ED is made of gold (Au), the solder pattern SDP and the anode electrode 134 may be bonded to each other by applying heat and pressure during the transfer process of the light emitting element ED. Through eutectic bonding, the light emitting element ED may be bonded to the solder pattern SDP and the first electrode CE1 without a separate adhesive material. For example, the solder pattern SDP may be made of indium (In), tin (Sn), or an alloy thereof, but the embodiments of the present disclosure are not limited thereto. For example, the solder pattern SDP may be a bonding pad or a joining pad, but the embodiments of the present disclosure are not limited thereto.

Referring to FIGS. 8 and 9, a second insulating layer 116 may be positioned on the fourth organic insulating layer 115d, the first electrode CE1, and the bank BNK. For example, the second insulating layer 116 may be entirely positioned in the display area AA and the non-display area NA. For example, in order to prevent moisture permeation from the non-display area NA, the second insulating layer 116 may be positioned only in the display area AA. However, the embodiments of the present disclosure are not limited thereto.

The second insulating layer 116 may be composed of a single layer or a multiple layers of silicon oxide (SiOx) or silicon nitride (SiNx), which is an inorganic film material, but the embodiments of the present disclosure are not limited thereto.

According to the present disclosure, the second insulating layer 116 serving as a passivation layer may be positioned on the plurality of signal wires TL, the plurality of first electrodes CE1, the plurality of contact electrodes CCE, and the fourth organic insulating layer 115d. For example, the second insulating layer 116 may be positioned in the display area AA, the first non-display area NA1, and the second non-display area NA2. A portion of the second insulating layer 116 positioned in the bending area BA may be removed. In the second non-display area NA2, a portion of the second insulating layer 116 covering the plurality of pad electrodes PE may be removed. Since the second insulating layer 116 is positioned to cover regions other than the bending area BA and the regions where the plurality of pad electrodes PE and the solder pattern SDP are positioned, permeation of moisture or impurities into the light emitting element ED may be reduced. For example, the second insulating layer 116 may be composed of a single layer or multiple layers of silicon oxide (SiOx) or silicon nitride (SiNx), which is an inorganic film material, but the embodiments of the present disclosure are not limited thereto. For example, the second insulating layer 116 may be a planarization layer or an insulating layer, but the embodiments of the present disclosure are not limited thereto. For example, the second insulating layer 116 may include a hole that exposes the solder pattern SDP.

In each of the plurality of sub-pixels, the light emitting element ED may be positioned on the solder pattern SDP. The first light emitting element 130 may be positioned in the first sub-pixel SP1. The second light emitting element 140 may be positioned in the second sub-pixel SP2. The third light emitting element 150 may be positioned in the third sub-pixel SP3.

The light emitting element ED may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the embodiments of the present disclosure are not limited thereto.

Referring to FIGS. 9 and 10, the first light emitting element 130 may include the anode electrode 134, a first semiconductor layer 131, an active layer 132, a second semiconductor layer 133, the cathode electrode 135, and an encapsulation film 136, but the embodiments of the present disclosure are not limited thereto. For example, the first light emitting element 130 may not include the encapsulation film 136. The first semiconductor layer 131 may be positioned on the solder pattern SDP. The second semiconductor layer 133 may be positioned on the first semiconductor layer 131.

For example, one of the first semiconductor layer 131 and the second semiconductor layer 133 may be implemented as a compound semiconductor of a group III-V or a group II-VI and may be doped with an impurity (or dopant). For example, one of the first semiconductor layer 131 and the second semiconductor layer 133 may be a semiconductor layer doped with an n-type impurity, while the other may be a semiconductor layer doped with a p-type impurity, but the embodiments of the present disclosure are not limited thereto. For example, at least one of the first semiconductor layer 131 and the second semiconductor layer 133 may be a layer in which an n-type or p-type impurity is doped into a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the embodiments of the present disclosure are not limited thereto. For example, the n-type impurity may be silicon (Si), germanium (Ge), selenium (Se), carbon (C), tellurium (Te), or tin (Sn), but the embodiments of the present disclosure are not limited thereto. For example, the p-type impurity may be magnesium (Mg), zinc (Zn), calcium (Ca), strontium (Sr), barium (Ba), or beryllium (Be), but the embodiments of the present disclosure are not limited thereto.

For example, the first semiconductor layer 131 and the second semiconductor layer 133 may be a nitride semiconductor including an n-type impurity and a nitride semiconductor including a p-type impurity, respectively, but the embodiments of the present disclosure are not limited thereto. For example, the first semiconductor layer 131 may be a nitride semiconductor including a p-type impurity, and the second semiconductor layer 133 may be a nitride semiconductor including an n-type impurity, but the embodiments of the present disclosure are not limited thereto.

The active layer 132 may be positioned between the first semiconductor layer 131 and the second semiconductor layer 133. The active layer 132 may emit light by receiving holes and electrons from the first semiconductor layer 131 and the second semiconductor layer 133. For example, the active layer 132 may be configured as one of a single well structure, a multiple well structure, a single quantum well structure, a multi-quantum well (MQW) structure, a quantum dot structure, and a quantum wire structure, but the embodiments of the present disclosure are not limited thereto. For example, the active layer 132 may be formed of indium gallium nitride (InGaN) or gallium nitride (GaN), but the embodiments of the present disclosure are not limited thereto.

In another example, the active layer 132 may include a multi-quantum well (MQW) structure having a well layer and a barrier layer with a higher bandgap than that of the well layer. For example, the active layer 132 may be configured to include an InGaN layer as the well layer and an AlGaN layer as the barrier layer, but the embodiments of the present disclosure are not limited thereto.

The anode electrode 134 may be positioned between the first semiconductor layer 131 and the solder pattern SDP. For example, the anode electrode 134 may electrically connect the first semiconductor layer 131 to the first electrode CE1. An anode voltage outputted from the driving circuit chip PD may be applied to the first semiconductor layer 131 through the signal wire TL, the first electrode CE1, and the anode electrode 134. For example, the anode electrode 134 may be formed of a conductive material capable of eutectic bonding with the solder pattern SDP, but the embodiments of the present disclosure are not limited thereto. For example, the anode electrode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof, but the embodiments of the present disclosure are not limited thereto.

The cathode electrode 135 may be positioned on the second semiconductor layer 133. For example, the cathode electrode 135 may electrically connect the second semiconductor layer 133 to the second electrode CE2. A cathode voltage outputted from the driving circuit chip PD may be applied to the second semiconductor layer 133 through the contact electrode CCE, the second electrode CE2, and the cathode electrode 135. The cathode electrode 135 may be formed of a transparent conductive material such that light emitted from the light emitting element ED can be directed upward from the light emitting element ED, but the embodiments of the present disclosure are not limited thereto. For example, the cathode electrode 135 may formed of a material such as indium tin oxide (ITO), indium zinc oxide (IZO), or indium gallium zinc oxide (IGZO), but the embodiments of the present disclosure are not limited thereto.

The encapsulation film 136 may be positioned on at least portions of the first semiconductor layer 131, the active layer 132, the second semiconductor layer 133, the anode electrode 134, and the cathode electrode 135. For example, the encapsulation film 136 may surround at least portions of the first semiconductor layer 131, the active layer 132, the second semiconductor layer 133, the anode electrode 134, and the cathode electrode 135. For example, the encapsulation film 136 may protect the first semiconductor layer 131, the active layer 132, and the second semiconductor layer 133. For example, the encapsulation film 136 may be positioned on the side surface of the first semiconductor layer 131, the side surface of the active layer 132, and the side surface of the second semiconductor layer 133.

For example, the encapsulation film 136 may be positioned on at least portions of the anode electrode 134 and the cathode electrode 135, e.g., on an edge portion (or peripheral portion or one side) of the anode electrode 134 and an edge portion (or peripheral portion or one side) of the cathode electrode 135. At least a portion of the anode electrode 134 may be exposed from the encapsulation film 136, so that the anode electrode 134 may be connected to the solder pattern SDP. For example, at least a portion of the cathode electrode 135 may be exposed from the encapsulation film 136, so that the cathode electrode 135 may be connected to the second electrode CE2. For example, the encapsulation film 136 may be formed of an insulating material such as silicon nitride (SiNx) or silicon oxide (SiOx), but the embodiments of the present disclosure are not limited thereto.

For example, the encapsulation film 136 may have a structure in which a reflective material is dispersed in a resin layer, but the embodiments of the present disclosure are not limited thereto. For example, the encapsulation film 136 may be manufactured as a reflector having various structures, but the embodiments of the present disclosure are not limited thereto. Light emitted from the active layer 132 may be reflected upward by the encapsulation film 136, thereby improving light extraction efficiency. For example, the encapsulation film 136 may serve as a reflective layer, but the embodiments of the present disclosure are not limited thereto.

According to the present disclosure, although the light emitting element ED has been described as having a vertical structure, the embodiments of the present disclosure are not limited thereto. For example, the light emitting element ED may have a lateral structure or a flip-chip structure.

Although the first light emitting element 130 has been described with reference to FIG. 10, the second light emitting element 140 and the third light emitting element 150 may have substantially the same structure as the first light emitting element 130. For example, the second light emitting element 140 and the third light emitting element 150 may have the first semiconductor layer 131, the active layer 132, the second semiconductor layer 133, the anode electrode 134, the cathode electrode 135, and the encapsulation film 136 substantially in the same manner as the first light emitting element 130.

According to the present disclosure, a first optical layer 117a surrounding the plurality of light emitting elements ED in the display area AA may be positioned on the second insulating layer 116. For example, the first optical layer 117a may be positioned to cover the plurality of light emitting elements ED and the banks BNK in regions of the plurality of sub-pixels. For example, the first optical layer 117a may cover the bank BNK, a portion of the second insulating layer 116 and the spaces between the plurality of light emitting elements ED. The first optical layer 117a may be positioned between the plurality of banks BNK and between the plurality of light emitting elements ED included in one pixel PX, or may cover those spaces. For example, the first optical layer 117a may extend in a first direction X and may be separated in a second direction Y. For example, the first optical layer 117a may be positioned between the second insulating layer 116 and the second electrode CE2 to surround the side portions of the light emitting element ED and the bank BNK, but the embodiments of the present disclosure are not limited thereto. For example, the first optical layer 117a may be a diffusion layer, a sidewall diffusion layer, or the like, but the embodiments of the present disclosure are not limited thereto.

The first optical layer 117a may include an organic insulating material in which fine particles are dispersed, but the embodiments of the present disclosure are not limited thereto. For example, the first optical layer 117a may be formed of siloxane in which fine metal particles such as titanium dioxide (TiO₂) particles are dispersed, but the embodiments of the present disclosure are not limited thereto. Light from the plurality of light emitting elements ED may be scattered by the fine particles dispersed in the first optical layer 117a and emitted to the outside of the display device 1000. Accordingly, the first optical layer 117a may improve the light extraction efficiency of the light emitted from the plurality of light emitting elements ED.

For example, the first optical layer 117a may be positioned in each of the plurality of pixels PX, or may be commonly positioned in some of the pixels PX arranged in the same row, but the embodiments of the present disclosure are not limited thereto. For example, the first optical layer 117a may be positioned in each of the plurality of pixels PX, or a single first optical layer 117a may be shared by the plurality of pixels PX. In another example, each of the plurality of sub-pixels may separately include the first optical layer 117a, but the embodiments of the present disclosure are not limited thereto.

According to the present disclosure, a second optical layer 117b may be positioned on the second insulating layer 116 in the display area AA. For example, the second optical layer 117b may be positioned to surround the first optical layer 117a. For example, the second optical layer 117b may be in contact with the side surface of the first optical layer 117a. For example, the second optical layer 117b may be positioned in regions between the plurality of pixels PX. However, the embodiments of the present disclosure are not limited thereto. For example, the second optical layer 117b may be a diffusion layer, a diffusion layer window, or a window diffusion layer, but the embodiments of the present disclosure are not limited thereto.

The second optical layer 117b may be formed of an organic insulating material, but the embodiments of the present disclosure are not limited thereto. The second optical layer 117b may be formed of the same material as the first optical layer 117a, but the embodiments of the present disclosure are not limited thereto. For example, the first optical layer 117a may include fine particles and the second optical layer 117b may not include fine particles. For example, the second optical layer 117b may be formed of siloxane, but the embodiments of the present disclosure are not limited thereto.

For example, the thickness of the first optical layer 117a may be smaller than that of the second optical layer 117b, but the embodiments of the present disclosure are not limited thereto. Accordingly, when viewed in a plan, a region where the first optical layer 117a is positioned may include a recessed portion that is recessed inward with respect to the top surface of the second optical layer 117b.

According to the present disclosure, the second electrode CE2 may be positioned on the first optical layer 117a and the second optical layer 117b. For example, the second electrode CE2 may be electrically connected to the plurality of contact electrodes CCE through contact holes of the second optical layer 117b. The second electrode CE2 may be positioned on the plurality of light emitting elements ED. For example, the second electrode CE2 may include a transparent conductive oxide such as indium tin oxide (ITO) or indium zinc oxide (IZO), but the embodiments of the present disclosure are not limited thereto. The second electrode CE2 may be positioned in contact with the cathode electrode 135. For example, the second electrode CE2 may overlap the first optical layer 117a. For example, the second electrode CE2 may cover the outer surface of the first optical layer 117a.

The second electrode CE2 may continuously extend in the first direction X of the substrate 110.

Accordingly, the second electrode CE2 may be commonly connected to the plurality of pixels PX arranged in the first direction X of the substrate 110. For example, the second electrode CE2 may be commonly connected to the plurality of pixels PX.

According to the present disclosure, the second electrode CE2 may continuously extend on the first optical layer 117a, the second optical layer 117b, and the light emitting elements ED. A region where the first optical layer 117a is positioned may include a recessed portion that is recessed inward with respect to the top surface of the second optical layer 117b. Accordingly, since a first portion of the second electrode CE2 positioned on the first optical layer 117a is positioned along the recessed portion, the first portion may be located at a position lower than a second portion of the second electrode CE2 positioned on the second optical layer 117b.

A third optical layer 117c may be positioned to overlap the plurality of light emitting elements and the first optical layer 117a. Since the third optical layer 117c is positioned on the second electrode CE2 and the plurality of light emitting elements ED, it may improve mura that may occur in some of the plurality of light emitting elements ED. For example, when transferring the plurality of light emitting elements ED onto the substrate 110 of the display device 1000, a region where gaps between the plurality of light emitting elements ED are not uniform may be formed due to process deviations or the like. If the gaps between the plurality of light emitting elements ED are not uniform, light exit regions of the respective light emitting elements ED may also be arranged non-uniformly, which may cause mura to be visually recognized by the user. Accordingly, by providing the third optical layer 117c configured to uniformly diffuse light above the plurality of light emitting elements ED, it is possible to reduce the likelihood that light emitted from certain light emitting elements ED is visually recognized as mura.

Therefore, the light emitted from the plurality of light emitting elements ED may be uniformly diffused by the third optical layer 117c and extracted to the outside of the display device 1000, thereby improving luminance uniformity of the display device 1000.

The third optical layer 117c may be formed of an organic insulating material in which fine particles are dispersed, but the embodiments of the present disclosure are not limited thereto. For example, the third optical layer 117c may be formed of siloxane in which fine metal particles such as titanium dioxide (TiO₂) particles are dispersed, but the embodiments of the present disclosure are not limited thereto. For example, the third optical layer 117c may be formed of the same material as the first optical layer 117a, but the embodiments of the present disclosure are not limited thereto. For example, the third optical layer 117c may be a diffusion layer, a top surface diffusion layer, or the like, but the embodiments of the present disclosure are not limited thereto.

According to the present disclosure, light from the plurality of light emitting elements ED may be scattered by the fine particles dispersed in the third optical layer 117c and emitted to the outside of the display device 1000. The third optical layer 117c may uniformly mix the light emitted from the plurality of light emitting elements ED, thereby further improving the luminance uniformity of the display device 1000. In addition, the light extraction efficiency of the display device 1000 may be improved by the light scattered by the fine particles, making it possible to operate the display device 1000 at lower power.

A black matrix BM may be positioned on the second electrode CE2, the first optical layer 117a, the second optical layer 117b, the third optical layer 117c, and a third insulating layer (not shown) in the display area AA. For example, the black matrix BM may fill the contact hole of the second optical layer 117b. The black matrix BM may be configured to cover the display area AA, and thus color mixing of light from the plurality of sub-pixels and external light reflection may be reduced. For example, the black matrix BM may also be positioned within the contact hole where the second electrode CE2 and contact electrode CCE are connected, thereby preventing light leakage between adjacent sub-pixels.

For example, the black matrix BM may be formed of an opaque material but the embodiments of the present disclosure are not limited thereto. For example, the black matrix BM may be formed of an organic insulating material to which a black pigment or black dye has been added, but the embodiments of the present disclosure are not limited thereto.

A cover layer 118 (see FIG. 8) may be positioned on the black matrix BM in the display area AA. The cover layer 119 may be formed of an organic insulating material, but the embodiments of the present disclosure are not limited thereto. For example, the cover layer 119 may be formed of photoresist, polyimide (PI), or a photoacryl-based material, but the embodiments of the present disclosure are not limited thereto. For example, the cover layer 118 may be an overcoat layer, an insulating layer, or the like, but the embodiments of the present disclosure are not limited thereto.

As shown in FIG. 1, the polarizing layer 293 may be positioned on the cover layer 118 via a first adhesive layer 291. The cover member 120 may be positioned on the polarizing layer 293 via a second adhesive layer 295. For example, the first adhesive layer 291 and the second adhesive layer 295 may include an optically clear adhesive (OCA), an optically clear resin (OCR), or a pressure sensitive adhesive (PSA), but the embodiments of the present disclosure are not limited thereto.

According to the present disclosure, the plurality of pad electrodes PE may be positioned on the fourth organic insulating layer 115d in the second non-display area NA2. For example, at least a portion of the plurality of pad electrodes PE may be exposed from the second insulating layer 116. For example, the plurality of pad electrodes PE may be electrically connected to the second-fourth connection wire 122d through a contact hole of the fourth organic insulating layer 115d.

An adhesive layer ACF may be positioned on the plurality of pad electrodes PE. The adhesive layer ACF may be an adhesive layer in which conductive balls are dispersed in an insulating material, but the embodiments of the present disclosure are not limited thereto. When heat or pressure is applied to the adhesive layer, the conductive balls may become electrically connected at portions where the heat or pressure is applied, thereby exhibiting conductive characteristics. By positioning the adhesive layer between the flexible circuit board (or flexible film) CB and the plurality of pad electrodes PE, the flexible circuit board (or flexible film) CB may be attached or bonded to the plurality of pad electrodes PE. For example, the adhesive layer may be an anisotropic conductive film, but the embodiments of the present disclosure are not limited thereto.

The flexible circuit board (or flexible film) CB (see FIG. 1) may be positioned on the adhesive layer. The flexible circuit board (or flexible film) CB may be electrically connected to the plurality of pad electrodes PE through the adhesive layer. Accordingly, a signal outputted from the flexible circuit board (or flexible film) CB and the printed circuit board may be transmitted to the driving circuit chip PD of the display area AA through the plurality of pad electrodes PE, the second-fourth connection wire 122d, the second-third connection wire 122c, the second-second connection wire 122b, and the second-first connection wire 122a.

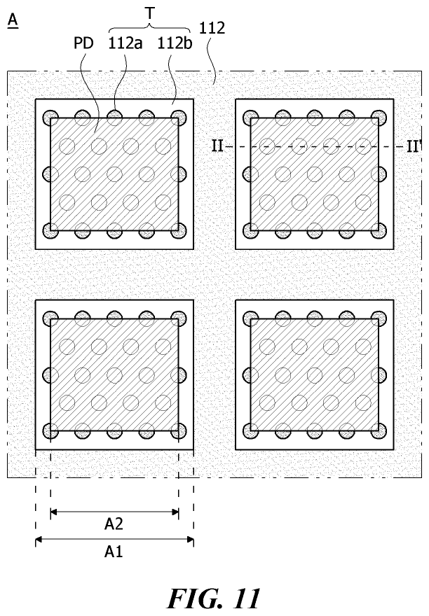

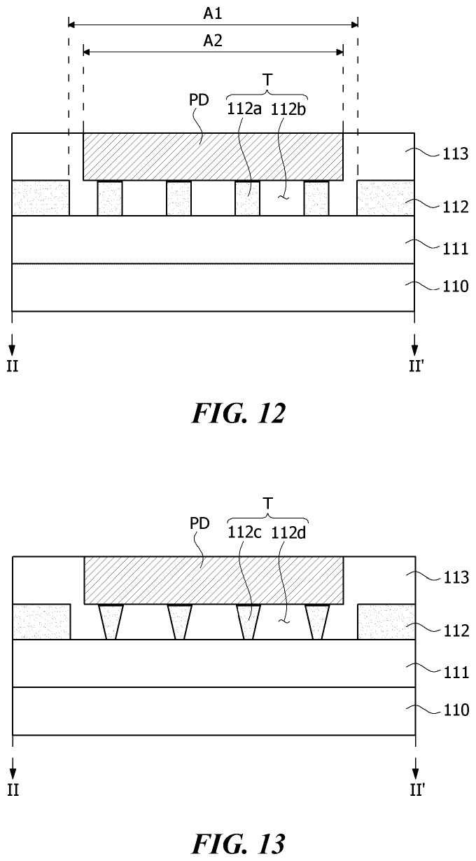

FIG. 11 is an enlarged plan view of a display device according to an embodiment of the present disclosure. FIG. 12 is a cross-sectional view taken along line II-II′ in FIG. 11. Specifically, FIG. 11 is an enlarged plan view showing the adhesive layer 112 including the driving circuit chip transfer portion T provided with the plurality of support patterns 112a spaced apart from each other, and the driving circuit chip PD positioned on the driving circuit chip transfer portion T of the adhesive layer 112. In addition, specifically, FIG. 12 is an enlarged cross-sectional view showing the driving circuit chip PD positioned on the driving circuit chip transfer portion T of the adhesive layer 112.

In the present disclosure, a description of the components including a planarization layer 113 positioned on the driving circuit chip PD has already been provided with reference to FIGS. 8 and 9, and thus will be omitted below.

Referring to FIGS. 11 and 12, in the display device according to one embodiment of the present disclosure, the buffer layer 111 may be positioned on the substrate 110, and the adhesive layer 112 may be positioned on the buffer layer 111. The adhesive layer 112 may be provided with the driving circuit chip transfer portion T. The driving circuit chip transfer portion T may include the plurality of support patterns 112a spaced apart from each other, and the pass holes 112b formed between the plurality of support patterns 112a.

The driving circuit chip PD may be positioned on the plurality of support patterns 112a of the driving circuit chip transfer portion T. An area A2 of the driving circuit chip PD may be smaller than an area A1 of the driving circuit chip transfer portion T. For example, since the area A2 of the driving circuit chip PD is smaller than the area A1 of the driving circuit chip transfer portion T at the time of transferring the driving circuit chip PD, the driving circuit chip PD may not entirely cover the driving circuit chip transfer portion T. For this reason, the pass hole 112b of the driving circuit chip transfer portion T may communicate with the outside, so that during the curing process of the adhesive layer 112 is performed after transferring the driving circuit chip PD, residual solvents, e.g., bubbles, remaining in the adhesive layer 112 may be discharged to the outside through the bubble pass 112b.

In addition, after the driving circuit chip PD is transferred, a portion of the planarization layer 113 positioned on the driving circuit chip PD needs to fill the pass hole 112b of the driving circuit chip transfer portion T, so that the area A1 of the driving circuit chip transfer portion T should be larger than the area A2 of the driving circuit chip PD. For example, in order for residual solvents in the adhesive layer 112 to be effectively discharged to the outside during the curing process of the adhesive layer 112 after the driving circuit chip PD is transferred onto the plurality of support patterns 112a of the driving circuit chip transfer portion T, the pass hole 112b should be in communication with the outside. Accordingly, in order not to block the pass hole 112b of the driving circuit chip transfer portion T, the driving circuit chip PD should have a smaller area than the driving circuit chip transfer portion T. However, the embodiments of the present disclosure are not limited thereto.

Specifically, referring to FIG. 12, the buffer layer 111 may be positioned in the remaining areas of the substrate 110 excluding the bending area BA, e.g., in the display area AA and the non-display area NA. The buffer layer 111 may include the first buffer layer 111a and the second buffer layer 111b shown in FIGS. 8 and 9.

The buffer layer 111 may be positioned in the display area AA, but may not be positioned in the non-display area NA. However, the embodiments of the present disclosure are not limited thereto. The buffer layer 111 may reduce the permeation of moisture or impurities through the substrate 110. The buffer layer 111 may be formed of an inorganic insulating material. For example, the buffer layer 111 may be composed of a single layer or multiple layers of silicon oxide (SiOx) or silicon nitride (SiNx), but the embodiments of the present disclosure are not limited thereto. Additionally, in order to prevent moisture permeation from the non-display area NA, the buffer layer 111 may be positioned only in the display area AA. However, the embodiments of the present disclosure are not limited thereto. The buffer layer 111 may be composed of a single layer or multiple layers of silicon oxide (SiOx) or silicon nitride (SiNx), which is an inorganic film material, but the embodiments of the present disclosure are not limited thereto.

The adhesive layer 112 may be positioned on the buffer layer 111. For example, the adhesive layer 112 may be formed of any one of an adhesive polymer, an epoxy resin, a UV-curable resin, a polyimide-based material, an acrylate-based material, a urethane-based material, or polydimethylsiloxane (PDMS), but the embodiments of the present disclosure are not limited thereto.

The adhesive layer 112 may be provided with the driving circuit chip transfer portion T to which the driving circuit chip PD is transferred and bonded. The driving circuit chip transfer portion T may include the plurality of support patterns 112a spaced apart from each other such that the driving circuit chip PD is transferred and supported. In addition, the pass hole 112b may be provided between the plurality of support patterns 112a spaced apart from each other. The pass holes 112b between the plurality of support patterns 112a may communicate with each other and be exposed to the outside. However, the present disclosure is not limited thereto.

Accordingly, by forming the pass hole 112b between the plurality of support patterns 112a in the driving circuit chip transfer portion T of the adhesive layer 112, foreign particles may be discharged to the outside through the pass hole 112b, thereby reducing the likelihood that the foreign particles P remain on the surface of the adhesive layer 112 including the plurality of support patterns 112a. As a result, the transfer yield of the driving circuit chip during the fabrication of the display device may be increased.

After the driving circuit chip PD is transferred, during the curing process of the adhesive layer 112, not only residual solvents, e.g., bubbles B, remaining in the adhesive layer 112 but also bubbles B present in the support patterns 112a may be discharged to the outside through the pass hole 112b. For example, during the curing process of the adhesive layer 112, residual solvents in the adhesive layer 112, e.g., big voids may be removed. Here, during the curing (baking) process performed after forming the planarization layer 113 around the transferred driving circuit chip PD for a planarization process, the residual solvents in the adhesive layer 112 may become big voids and may remain trapped in the adhesive layer 112 as voids. Accordingly, by allowing the residual solvents in the adhesive layer 112 to be discharged to the outside through the pass hole 112b of the driving circuit chip transfer portion T, problems such as driving circuit chip damage, delamination, or reduced reliability that can be caused by the solvents, e.g., the voids, during subsequent stacking processes of the display device may be prevented in advance.

In the display area AA, the driving circuit chip PD may be positioned on the adhesive layer 112. For example, the driving circuit chip PD may be positioned on the driving circuit chip transfer portion T of the adhesive layer 112. When the driving circuit chip PD is implemented as a driving driver, the driving driver may be mounted on the adhesive layer 112 through a transfer process, but the embodiments of the present disclosure are not limited thereto.

Specifically, since the area A2 of the driving circuit chip PD is smaller than the area A1 of the driving circuit chip transfer portion T, the driving circuit chip PD does not entirely cover the driving circuit chip transfer portion T even when the driving circuit chip PD is positioned on the plurality of support patterns 112a of the driving circuit chip transfer portion T. Accordingly, the pass hole 112b between the plurality of support patterns 112a may communicate with the outside.

Accordingly, after the driving circuit chip PD is transferred onto the driving circuit chip transfer portion T, during the curing of the adhesive layer 112, solvents containing the bubbles B that may exist within the plurality of support patterns 112a may be discharged to the outside through the pass holes 112b and released into the atmosphere, even without a separate baking process.

Referring to FIG. 12, the planarization layer 113 may be positioned on the driving circuit chip PD and the adhesive layer 112. The planarization layer 113 may be positioned to surround the side surface of the driving circuit chip PD, but the embodiments of the present disclosure are not limited thereto. For example, the planarization layer 113 may be positioned to cover at least a portion of the top surface of the driving circuit chip PD.

The planarization layer 113 may be filled into the pass hole 112b located below the driving circuit chip PD. The planarization layer 113 may be formed of an organic insulating material, but the embodiments of the present disclosure are not limited thereto. For example, the planarization layer 113 may be formed of photoresist, polyimide (PI), or photoacryl-based material, but the embodiments of the present disclosure are not limited thereto. For example, the planarization layer 113 may serve as an overcoat layer or an insulating layer, but the embodiments of the present disclosure are not limited thereto.

FIG. 13 is a cross-sectional view taken along line II-II′ in FIG. 11 and illustrates a cross-sectional view of a display device according to another embodiment of the present disclosure. For example, FIG. 13 illustrates, as another embodiment of the present disclosure, an enlarged cross-sectional view in which the cross-section of a plurality of support patterns 112c forming the driving circuit chip transfer portion T has a reverse tapered shape.

FIG. 13 differs from FIG. 12, which illustrates one embodiment of the present disclosure, only in the cross-sectional structure of the plurality of support patterns 112c forming the driving circuit chip transfer portion T, and the other components may be the same as those in the embodiment of FIG. 12.

Referring to FIG. 13, in the display device according to another embodiment of the present disclosure, the buffer layer 111 may be positioned on the substrate 110, and the adhesive layer 112 may be positioned on the buffer layer 111. The adhesive layer 112 may be provided with the driving circuit chip transfer portion T. The driving circuit chip transfer portion T may include the plurality of support patterns 112c spaced apart from each other, and a pass hole 112d formed between the plurality of support patterns 112c.

Here, the plurality of support patterns 112c spaced apart from each other in the driving circuit chip transfer portion T may have a reverse tapered cross-sectional structure. For example, the plurality of support patterns 112c may each have a narrower cross-sectional width toward the bottom. For example, the cross-section of the plurality of support patterns 112c may include various cross-sectional structures, including not only the reverse tapered structure but also a normal tapered structure. However, the embodiments of the present disclosure are not limited thereto.

The driving circuit chip PD may be positioned on the plurality of support patterns 112c of the driving circuit chip transfer portion T. The area of the driving circuit chip PD may be smaller than the area of the driving circuit chip transfer portion T. For example, since the area of the driving circuit chip PD is smaller than the area of the driving circuit chip transfer portion T at the time of transferring the driving circuit chip PD, the driving circuit chip PD may not entirely cover the driving circuit chip transfer portion T. For this reason, the bubble pass 112d of the driving circuit chip transfer portion T may communicate with the outside, so that during the curing process of the adhesive layer 112 that is performed after transferring the driving circuit chip PD, residual solvents, e.g., bubbles B, remaining in the adhesive layer 112 may be discharged to the outside through the pass hole 112d.

In addition, after the driving circuit chip PD is transferred, a portion of the planarization layer 113 positioned on the driving circuit chip PD needs to fill the pass hole 112d of the driving circuit chip transfer portion T, so that the area of the driving circuit chip transfer portion T should be larger than the area of the driving circuit chip PD. For example, in order for residual solvents in the adhesive layer 112 to be effectively discharged to the outside during the curing process of the adhesive layer 112 after the driving circuit chip PD is transferred onto the plurality of support patterns 112c of the driving circuit chip transfer portion T, the pass hole 112d should be in communication with the outside. Accordingly, in order not to block the pass hole 112d of the driving circuit chip transfer portion T, the driving circuit chip PD should have a smaller area than the driving circuit chip transfer portion T. However, the embodiments of the present disclosure are not limited thereto.

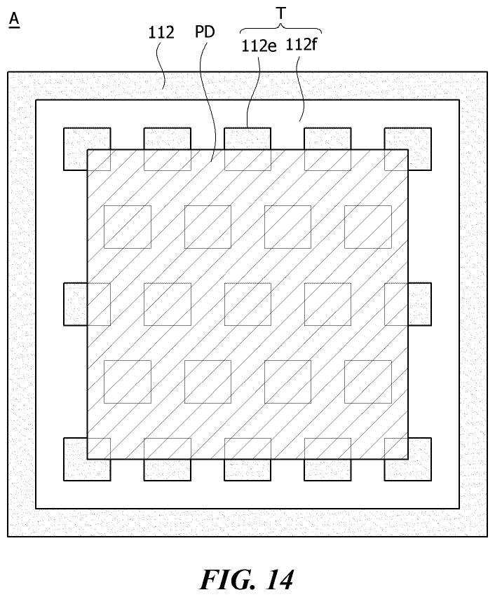

FIG. 14 is an enlarged plan view of a display device according to another embodiment of the present disclosure. For example, FIG. 14 illustrates, as still another embodiment of the present disclosure, an enlarged plan view in which the top surface of a plurality of support patterns 112e, on which the driving circuit chip PD is positioned, has a quadrilateral shape.

FIG. 14 differs from FIG. 12, which illustrates one embodiment of the present disclosure, only in the structure of the top surface of the plurality of support patterns 112e forming the driving circuit chip transfer portion T, and the other components may be the same as those in the embodiment of FIG. 12.

Referring to FIG. 14, in the display device according to still another embodiment of the present disclosure, the buffer layer 111 may be positioned on the substrate 110, and the adhesive layer 112 may be positioned on the buffer layer 111. The adhesive layer 112 may be provided with the driving circuit chip transfer portion T. The driving circuit chip transfer portion T may include the plurality of support patterns 112e spaced apart from each other, and a pass hole 112f formed between the plurality of support patterns 112c.

Here, the plurality of support patterns 112e spaced apart from each other in the driving circuit chip transfer portion T may have a quadrilateral top surface and a vertical side surface. For example, the top surface of the plurality of support patterns 112e may be formed in a polygonal shape, such as a triangular shape or a pentagonal shape, other than a quadrilateral shape, or in a circular shape. However, the embodiments of the present disclosure are not limited thereto.

The driving circuit chip PD may be positioned on the plurality of support patterns 112e of the driving circuit chip transfer portion T. The area of the driving circuit chip PD may be smaller than the area of the driving circuit chip transfer portion T. For example, since the area A2 of the driving circuit chip PD is smaller than the area A1 of the driving circuit chip transfer portion T at the time of transferring the driving circuit chip PD, the driving circuit chip PD may not entirely cover the driving circuit chip transfer portion T. For this reason, the pass hole 112f of the driving circuit chip transfer portion T may communicate with the outside, so that during the curing process of the adhesive layer 112 that is performed after transferring the driving circuit chip PD, residual solvents, e.g., bubbles, remaining in the adhesive layer 112 may be discharged to the outside through the pass hole 112f.

In addition, after the driving circuit chip PD is transferred, a portion of the planarization layer 113 positioned on the driving circuit chip PD needs to fill the pass hole 112f of the driving circuit chip transfer portion T, so that the area of the driving circuit chip transfer portion T should be larger than the area of the driving circuit chip PD. For example, in order for residual solvents in the adhesive layer 112 to be effectively discharged to the outside during the curing process of the adhesive layer 112 after the driving circuit chip PD is transferred onto the plurality of support patterns 112e of the driving circuit chip transfer portion T, the pass hole 112f should be in communication with the outside. Accordingly, in order not to block the pass hole 112f of the driving circuit chip transfer portion T, the driving circuit chip PD should have a smaller area than the driving circuit chip transfer portion T. However, the embodiments of the present disclosure are not limited thereto.

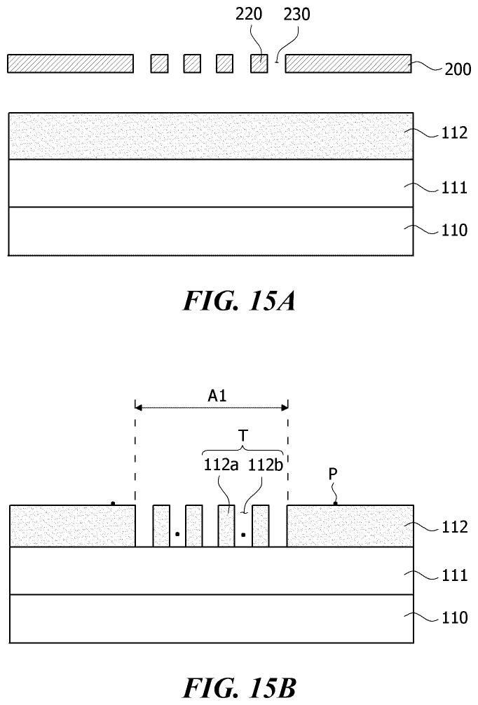

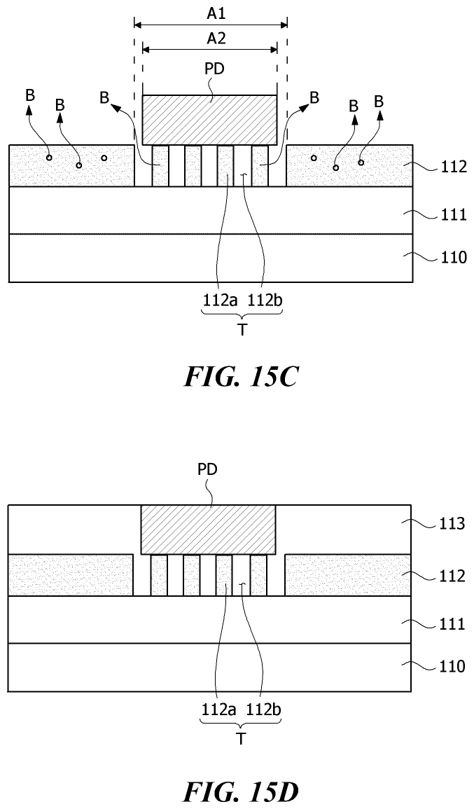

FIGS. 15A to 15D are cross-sectional views illustrating fabricating processes of a display device according to an embodiment of the present disclosure.

In the present disclosure, the processes of positioning components other than the buffer layer 111, the adhesive layer 112, the driving circuit chip PD, and the planarization layer 113 on the substrate 110 have been described above with reference to FIGS. 8 and 9, and thus a description thereof will be omitted below.

Referring to FIG. 15A, the buffer layer 111 may first be positioned on the substrate 110. For example, the buffer layer 111 may be positioned in the remaining areas of the substrate 110 excluding the bending area BA, e.g., in the display area AA and the non-display area NA. The buffer layer 111 may include the first buffer layer 111a and the second buffer layer 111b shown in FIGS. 8 and 9.

The buffer layer 111 may be positioned in the display area AA, but may not be positioned in the non-display area NA. However, the embodiments of the present disclosure are not limited thereto. The buffer layer 111 may reduce the permeation of moisture or impurities through the substrate 110. The buffer layer 111 may be formed of an inorganic insulating material. For example, the buffer layer 111 may be composed of a single layer or multiple layers of silicon oxide (SiOx) or silicon nitride (SiNx), but the embodiments of the present disclosure are not limited thereto. In order to prevent moisture permeation from the non-display area NA, the buffer layer 111 may be positioned only in the display area AA. However, the embodiments of the present disclosure are not limited thereto. The buffer layer 111 may be composed of a single layer or multiple layers of silicon oxide (SiOx) or silicon nitride (SiNx), which is an inorganic film material, but the embodiments of the present disclosure are not limited thereto.

Next, the adhesive layer 112 may be positioned on the buffer layer 111. For example, the adhesive layer 112 may be formed of any one of an adhesive polymer, an epoxy resin, a UV-curable resin, a polyimide-based material, an acrylate-based material, a urethane-based material, and polydimethylsiloxane (PDMS), but the embodiments of the present disclosure are not limited thereto.

Subsequently, an exposure mask 200 having a plurality of light blocking patterns 220 spaced apart from each other may be positioned above the adhesive layer 112. The exposure mask 200 may include the plurality of light blocking patterns 220 spaced apart from each other and a light transmitting region 230 between the light blocking patterns. However, the embodiments of the present disclosure are not limited thereto.

Next, referring to FIG. 15B, the adhesive layer 112 may be selectively removed through an exposure and development process using the exposure mask 200 having the plurality of light blocking patterns 220 spaced apart from each other, thereby forming the driving circuit chip transfer portion T including the plurality of support patterns 112a spaced apart from each other and the pass hole 112b in the adhesive layer 112. In this case, the pass hole 112b may be formed between the plurality of support patterns 112a spaced apart from each other. The pass holes 112b between the plurality of support patterns 112a may communicate with each other and be exposed to the outside. However, the present disclosure is not limited thereto.

Accordingly, by forming the pass hole 112b between the plurality of support patterns 112a in the driving circuit chip transfer portion T of the adhesive layer 112, foreign particles P may be discharged to the outside through the pass hole 112b, thereby reducing the likelihood that the foreign particles remain on the surface of the adhesive layer 112 including the plurality of support patterns 112a. As a result, the transfer yield of the driving circuit chip during the fabrication of the display device may be increased.

Subsequently, referring to FIG. 15C, the driving circuit chip PD may be transferred and positioned on the driving circuit chip transfer portion T of the adhesive layer 112 located in the display area AA. For example, when the driving circuit chip PD is implemented as a driving driver, the driving driver may be mounted on the adhesive layer 112 through a transfer process, but the embodiments of the present disclosure are not limited thereto.

In this case, the area A2 of the driving circuit chip PD may be smaller than the area A1 of the driving circuit chip transfer portion T. For example, since the area A2 of the driving circuit chip PD is smaller than the area A1 of the driving circuit chip transfer portion T, the driving circuit chip PD does not entirely cover the driving circuit chip transfer portion T even when the driving circuit chip PD is positioned on the plurality of support patterns 112a of the driving circuit chip transfer portion T. As a result, the pass hole 112b formed between the plurality of support patterns 112a may communicate with the outside.

Next, after the driving circuit chip PD is transferred, the adhesive layer 112 may undergo a curing process. In this case, by curing the adhesive layer 112, not only residual solvents, e.g., bubbles B, remaining in the adhesive layer 112 but also bubbles B present in the support patterns 112a may be discharged to the outside through the pass hole 112b. For example, during the curing process of the adhesive layer 112, residual solvents in the adhesive layer 112, e.g., big voids may be removed. Here, during the curing (baking) process performed after forming the planarization layer 113 around the transferred driving circuit chip PD for a planarization process, the residual solvents in the adhesive layer 112 may become big voids and may remain trapped in the adhesive layer 112 as voids.

Accordingly, by allowing the residual solvents in the adhesive layer 112 to be discharged to the outside through the pass hole 112b of the driving circuit chip transfer portion T, problems such as driving circuit chip damage, delamination, or reduced reliability that can be caused by the solvents, e.g., the voids, during subsequent stacking processes of the display device may be prevented in advance.

Next, referring to FIG. 15D, the planarization layer 113 may be positioned on the driving circuit chip PD and the adhesive layer 112. The planarization layer 113 may be formed of an organic insulating material, but the embodiments of the present disclosure are not limited thereto. For example, the planarization layer 113 may be formed of photoresist, polyimide (PI), or photoacryl-based material, but the embodiments of the present disclosure are not limited thereto. For example, the planarization layer 113 may serve as an overcoat layer or an insulating layer, but the embodiments of the present disclosure are not limited thereto.

The planarization layer 113 may be positioned to surround the side surface of the driving circuit chip PD, but the embodiments of the present disclosure are not limited thereto. For example, the planarization layer 113 may be positioned to cover at least a portion of the top surface of the driving circuit chip PD.

The planarization layer 113 may be filled into the pass hole 112b located below the driving circuit chip PD. Since the area A2 of the driving circuit chip PD is smaller than the area A1 of the driving circuit chip transfer portion T, the pass hole 112b may be exposed to the outside, and through the exposed portion, a portion of the planarization layer 113 may be filled into the pass hole 112b. For example, since the area A2 of the driving circuit chip PD is smaller than the area A1 of the driving circuit chip transfer portion T at the time of transferring the driving circuit chip PD, the driving circuit chip PD does not entirely cover the driving circuit chip transfer portion T. For this reason, the pass hole 112b of the driving circuit chip transfer portion T may communicate with the outside, so that during the curing process of the adhesive layer 112 that is performed after transferring the driving circuit chip PD, residual solvents, e.g., bubbles B, remaining in the adhesive layer 112 may be discharged to the outside through the bubble pass 112b.

In addition, after the driving circuit chip PD is transferred, a portion of the planarization layer 113 positioned on the driving circuit chip PD needs to fill the pass hole 112b of the driving circuit chip transfer portion T, so that the area A1 of the driving circuit chip transfer portion T should be larger than the area A2 of the driving circuit chip PD. For example, in order for residual solvents in the adhesive layer 112 to be effectively discharged to the outside during the curing process of the adhesive layer 112 after the driving circuit chip PD is transferred onto the plurality of support patterns 112a of the driving circuit chip transfer portion T, the pass hole 112b should be in communication with the outside. Accordingly, in order not to block the pass hole 112b of the driving circuit chip transfer portion T, the driving circuit chip PD should have a smaller area than the driving circuit chip transfer portion T. However, the embodiments of the present disclosure are not limited thereto.

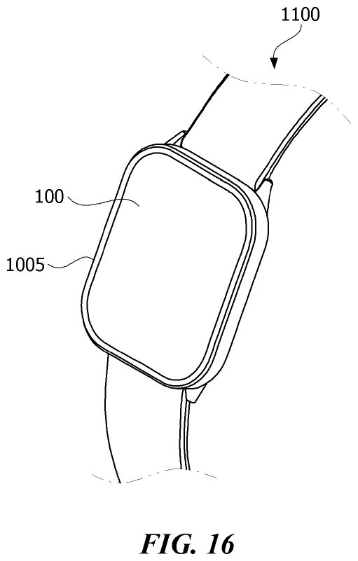

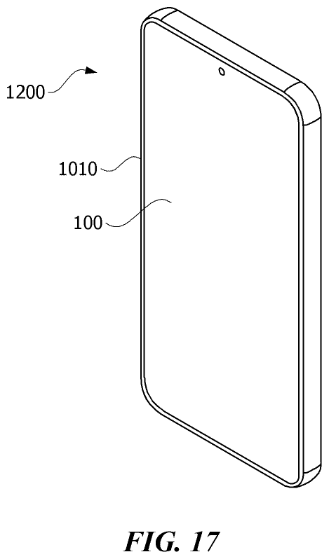

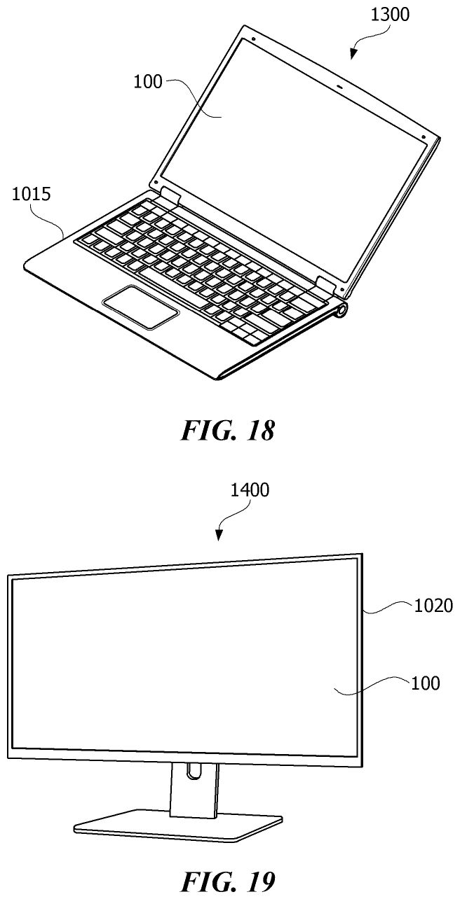

FIGS. 16 to 19 are views illustrating devices to which a display device according to embodiments of the present disclosure is applied.

Referring to FIGS. 16 to 19, the display device 1000 according to embodiments of the present disclosure may be included in various devices or electronic devices. For example, referring to FIGS. 16 to 19, various electronic devices may include a wearable device 1100, a mobile device 1200, a laptop 1300, and a monitor or TV 1400, but the embodiments of the present disclosure are not limited thereto.

Each of the wearable device 1100, the mobile device 1200, the laptop 1300, and the monitor or TV 1400 may include a case portion 1005, 1010, 1015, or 1020, and the display panel 100 and the display device 1000 according to the embodiments of the present disclosure described with reference to FIGS. 1 to 15.

The display device and the method for fabricating the same according to an embodiment of the present disclosure may include a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation, an in-vehicle display device, an in-theater display device, a television, a wallpaper device, a signage device, a gaming device, a laptop, a monitor, a camera, a camcorder, and a main board of a consumer electronics device.

The display device according to various embodiments of the present disclosure may be described as follows.

A display device according to various embodiments of the present disclosure may comprise an adhesive layer positioned on a substrate and including a driving circuit chip transfer portion having a plurality of support patterns spaced apart from each other and a pass hole; a driving circuit chip positioned on the plurality of support patterns; a planarization layer positioned on the driving circuit chip and the adhesive layer; an insulating layer positioned on the planarization layer; and a plurality of light emitting elements positioned on the insulating layer and connected to the driving circuit chip.

According to one embodiment of the present disclosure, an area of the driving circuit chip may be smaller than an area of the driving circuit chip transfer portion.

According to one embodiment of the present disclosure, a portion of the pass hole may be not covered by the driving circuit chip.

According to one embodiment of the present disclosure, the planarization layer may be filled in the pass hole.

According to one embodiment of the present disclosure, the plurality of light emitting elements may be electrically connected to the driving circuit chip through a connection wire.

According to one embodiment of the present disclosure, each of the plurality of light emitting elements may include an anode electrode positioned on a lower portion thereof and connected to the connection wire, and a cathode electrode positioned on an upper portion thereof and connected to a contact electrode to be electrically connected to the driving circuit chip.

According to one embodiment of the present disclosure, the display device may further include a first optical layer positioned between the plurality of light emitting elements.

According to one embodiment of the present disclosure, the display device may further include a second optical layer positioned on a side surface of the first optical layer; and a third optical layer positioned on the plurality of light emitting elements.

A display for fabricating a display device according to various embodiments of the present disclosure may comprise positioning an adhesive layer on a substrate, the adhesive layer including a driving circuit chip transfer portion having a plurality of support patterns spaced apart from each other and a pass hole positioned between the plurality of support patterns; positioning a driving circuit chip on the plurality of support patterns; positioning a planarization layer on the adhesive layer and the driving circuit chip; positioning an insulating layer on the planarization layer; and positioning a plurality of light emitting elements connected to the driving circuit chip on the insulating layer.

According to one embodiment of the present disclosure, an area of the driving circuit chip may be smaller than an area of the driving circuit chip transfer portion.

According to one embodiment of the present disclosure, a portion of the pass hole may be not covered by the driving circuit chip.

According to one embodiment of the present disclosure, the method for fabricating a display device may further include positioning a connection wire on the insulating layer to electrically connect the plurality of light emitting elements to the driving circuit chip.

According to one embodiment of the present disclosure, the method for fabricating a display device may further include positioning an anode electrode on a lower portion of the plurality of light emitting elements, the anode electrode being connected to the connection wire; and positioning a cathode electrode on a upper portion of the plurality of light emitting elements, the cathode electrode being connected to a contact electrode to be electrically connected to the driving circuit chip.

According to one embodiment of the present disclosure, the method for fabricating a display device may further include positioning a first optical layer between the plurality of light emitting elements.

According to one embodiment of the present disclosure, the method for fabricating a display device may further include positioning a second optical layer on a side surface of the first optical layer; and positioning a third optical layer on the plurality of light emitting elements.

Although embodiments of the present disclosure have been described in more detail with reference to the accompanying drawings, the present disclosure is not necessarily limited to the embodiments, and various modifications may be carried out without departing from the technical spirit of the present disclosure.

Therefore, the embodiments disclosed in the present disclosure are not intended to limit the technical spirit of the present disclosure, but intended to describe the same, and the scope of the technical spirit of the present disclosure is not limited by these embodiments. Therefore, it should be understood that the above-described embodiments are illustrative and not restrictive in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
an adhesive layer on a substrate, the adhesive layer including a driving circuit chip transfer portion having a plurality of support patterns spaced apart from each other and a pass hole;
a driving circuit chip on the plurality of support patterns;
a planarization layer on the driving circuit chip and the adhesive layer;
an insulating layer on the planarization layer; and
a plurality of light emitting elements on the insulating layer and connected to the driving circuit chip.

2. The display device of claim 1, wherein an area of the driving circuit chip is smaller than an area of the driving circuit chip transfer portion.

3. The display device of claim 1, wherein a portion of the pass hole is not covered by the driving circuit chip.

4. The display device of claim 1, wherein the planarization layer is disposed within the pass hole.

5. The display device of claim 1, further comprising a connection wire, wherein the plurality of light emitting elements are electrically connected to the driving circuit chip through the connection wire.

6. The display device of claim 5, wherein each of the plurality of light emitting elements includes an anode electrode on a lower portion thereof and connected to the connection wire, and a cathode electrode on an upper portion thereof and connected to a contact electrode configured to electrically connect to the driving circuit chip.

7. The display device of claim 2, further comprising:
a first optical layer between the plurality of light emitting elements.

8. The display device of claim 7, further comprising:
a second optical layer on a side surface of the first optical layer; and
a third optical layer on the plurality of light emitting elements.

9. A method for fabricating a display device, comprising:
positioning an adhesive layer on a substrate, the adhesive layer including a driving circuit chip transfer portion having a plurality of support patterns spaced apart from each other and a pass hole positioned between the plurality of support patterns;
positioning a driving circuit chip on the plurality of support patterns;
positioning a planarization layer on the adhesive layer and the driving circuit chip;
positioning an insulating layer on the planarization layer; and
positioning a plurality of light emitting elements connected to the driving circuit chip on the insulating layer.

10. The method for fabricating a display device of claim 9, wherein an area of the driving circuit chip is smaller than an area of the driving circuit chip transfer portion.

11. The method for fabricating a display device of claim 9, wherein a portion of the pass hole is not covered by the driving circuit chip.

12. The method for fabricating a display device of claim 9, further comprising:
positioning a connection wire on the insulating layer to electrically connect the plurality of light emitting elements to the driving circuit chip.

13. The method for fabricating a display device of claim 12, further comprising:
positioning an anode electrode on a lower portion of the plurality of light emitting elements, the anode electrode being connected to the connection wire; and
positioning a cathode electrode on an upper portion of the plurality of light emitting elements, the cathode electrode being connected to a contact electrode to be electrically connected to the driving circuit chip.

14. The method for fabricating a display device of claim 9, further comprising:
positioning a first optical layer between the plurality of light emitting elements.

15. The method for fabricating a display device of claim 14, further comprising:
positioning a second optical layer on a side surface of the first optical layer; and
positioning a third optical layer on the plurality of light emitting elements.

16. The display device of claim 1, wherein the pass hole, in operation, is configured to allow discharge of foreign particles or residual solvents from the adhesive layer.
